(19) United States
(12) Patent Application Publication
(10) Pub. No.: US 2015/0366047 A1
(43) Pub. Date: Dec. 17, 2015

(54) METAL FOIL-CLAD SUBSTRATE, CIRCUIT BOARD AND HEATING-ELEMENT MOUNTING SUBSTRATE

(71) Applicant: SUMITOMO BAKELITE CO., LTD., Tokyo (JP)

(72) Inventors: Shu Okasaka, Tokyo (JP); Toshio Komiyatani, Tokyo (JP); Koji Koizumi, Tokyo (JP); Takayuki Baba, Tokyo (JP)

(73) Assignee: SUMITOMO BAKELITE CO., LTD., Tokyo (JP)

(21) Appl. No.: 14/732,051

(22) Filed: Jun. 5, 2015

(30) Foreign Application Priority Data
Jun. 13, 2014 (JP) 2014-122848

(51) Int. Cl. H05K 1/02; H05K 1/03; H05K 1/18

(52) U.S. Cl. CPC H05K 1/0201; H05K 1/181; H05K 1/028; H05K 1/0373; H05K 2201/0355; H05K 2201/0215

(57) ABSTRACT

A metal foil-clad substrate used for forming a circuit board mounting and electrically connecting a heat element is provided. The metal foil-clad substrate includes: a metal foil having one surface; a resin layer formed on the one surface of the metal foil; a heat radiation metal plate formed on a surface of the resin layer opposite to the metal foil; an insulating part formed on the surface of the resin layer opposite to the metal foil; and at least one bending portion in which the metal foil, the resin layer and the insulating part are bended to a side of the metal foil or the insulating part. The insulating part is constituted of a cured material of a first resin composition containing a first thermosetting resin. The resin layer is constituted of a cured material or a solidified material of a second resin composition containing a resin material.

### CROSS-REFERENCE TO RELATED APPLICATION

This application is based on and claims a priority from a Japanese Patent Application No. 2014-122848 filed on Jun. 13, 2014, which is hereby expressly incorporated by reference herein in its entirety.

### BACKGROUND OF THE INVENTION

1. Field of the Invention

The present invention relates to a metal foil-clad substrate, a circuit board and a heating-element mounting substrate.

2. Description of the Related Art

In recent years, from a point of view of utilizing electric energy efficiently, attention is paid to a SiC/GaN power semiconductor device which mounts elements using SiC (silicon carbide) and GaN (gallium nitride) (e.g. patent document 1).

It is possible for these elements to not only lower power loss drastically but also active even under conditions of higher voltage, high current and a high temperature reaching 300° C. as compared with a conventional element using Si. Therefore, the SiC/GaN power semiconductor device is expected to use for applications for which it is difficult to be used in a conventional Si power semiconductor device.

In this way, it becomes possible to active the elements (semiconductor element) in themselves using SiC/GaN under the harsh conditions as described above. Therefore, there is a purpose of preventing heat generated due to drive of the semiconductor element being a heating element from affecting another member mounted onto a circuit board as well as the semiconductor element in itself in the circuit board mounting the semiconductor device having the elements. In order to achieve this purpose, it is required to efficiently radiate the heat through the circuit board.

Such a requirement is made for not only the semiconductor device but also the circuit board which mounts another heating element such as a light emitting device including a light-emitting diode and the like.

Further, it is required to mount the circuit board onto another structure without any limitation to a whole shape of another structure (a housing provided with an electronic device and the like) to mount the circuit board mounting the semiconductor device. Furthermore, it is required to downsize another structure.

The patent document 1: JPA 2005-167035.

### SUMMARY OF THE INVENTION

It is an object of the present invention to provide a metal foil-clad substrate that is capable of producing a circuit board to be mounted onto another structure without any limitation to a whole shape of another structure and efficiently radiating heat generated by a heating element to be mounted. Further, it is another object of the present invention to provide the circuit board produced by using such a metal foil-clad substrate and a heating-element mounting substrate in which the heating element is mounted onto the circuit board.

In order to achieve the objects described above, the present invention includes the following features (1) to (12).

(1) A metal foil-clad substrate used for forming a circuit board mounting and electrically connecting a heat element generating a heat, the metal foil-clad substrate comprising:

a metal foil having one surface;

a resin layer formed on the one surface of the metal foil;

a heat radiation metal plate formed on a surface of the resin layer opposite to the metal foil and radiating the heat generated by the heat element, wherein the surface of the resin layer includes a first area covering an area to mount the heat element and a second area except the first area in a planer view of the resin layer, and the heat radiation metal plate is formed to correspond to the first area;

an insulating part formed on the surface of the resin layer opposite to the metal foil so as to correspond to the second area in the planer view of the resin layer; and

at least one bending portion in which the metal foil, the resin layer and the insulating part are bended to a side of the metal foil or the insulating part in the second area,

wherein the insulating part is constituted of a cured material of a first resin composition containing a first thermosetting resin, and

wherein the resin layer is constituted of a cured material or a solidified material of a second resin composition containing a resin material.

(2) The metal foil-clad substrate according to the above feature (1), wherein the at least one bending portion includes a plurality of bending portions having two bending portions, and the plurality of bending portion is positioned in a direction of getting away from the first area in the second area, and

wherein one of the two bending portions is bended at the side of the metal foil and the other of the two bending portions is bended at the side of the insulating part.

(3) The metal foil-clad substrate according to the above feature (1) or (2), wherein the resin material includes a second thermosetting resin.

(4) The metal foil-clad substrate according to the above feature (3), wherein the second thermosetting resin includes an epoxy resin.

(5) The metal foil-clad substrate according to any one of the above features (1) to (4), wherein the resin material includes a resin component of which weight average molecular weight is in the range of 1.0×10⁴ to 1.0×10⁵.

(6) The metal foil-clad substrate according to any one of the above features (1) to (5), wherein the second resin composition contains a filler further.

(7) The metal foil-clad substrate according to the above feature (6), wherein the filler is a granular body constituted of aluminum oxide as a main component thereof.

(8) The metal foil-clad substrate according to the above feature (6) or (7), wherein the filler is dispersed at the side of the insulating part in the resin layer.

(9) The metal foil-clad substrate according to any one of the above features (1) to (8), wherein the first thermosetting resin includes a phenol resin.

(10) The metal foil-clad substrate according to any one of the above features (1) to (9), wherein the first resin composition and the second resin composition are different from each other.

(11) The circuit board formed using the metal foil-clad substrate according to any one of the above features (1) to (10), the circuit board comprising:

a circuit formed by performing a patterning of the metal foil, and having terminals to electrically connect the heat element.

(12) A heat-element mounting substrate, comprising:

the circuit board according to the above feature (11); and

the heat element mounted onto the circuit board and electrically connected to the terminals.

### EFFECT OF THE INVENTION

With the configuration of the metal foil-clad substrate of the present invention, it is possible to produce the circuit board that is capable of efficiently radiating the heat generated by the heating element to be mounted.

Therefore, with the configuration of the heating-element mounting substrate in which the heating element is mounted onto the circuit board of the present invention, it is possible to efficiently radiate the heat generated by the heating element through the circuit board in the heating-element mounting substrate.

Furthermore, with the configuration of the metal foil-clad substrate of the present invention, it is possible to mount the circuit board produced from the metal foil-clad substrate onto another structure without any limitation to the whole shape of another structure.

### BRIEF DESCRIPTION OF THE DRAWINGS

FIG. 1 is a vertical cross-sectional view which shows a first embodiment of a heating-element mounting substrate of the present invention.

FIG. 2 is a view (plan view) seen from a direction of the arrow A in FIG. 1.

FIGS. 3(a) to 3(d) are a view to illustrate a method of producing a metal foil-clad substrate used for producing the heating-element mounting substrate of FIG. 1.

FIGS. 4(a) and 4(b) are a view to illustrate a method of producing a metal foil-clad substrate used for producing the heating-element mounting substrate of FIG. 1.

FIG. 5 is a vertical cross-sectional view which shows a second embodiment of a heating-element mounting substrate of the present invention.

FIG. 6 is a vertical cross-sectional view which shows a third embodiment of a heating-element mounting substrate of the present invention.

FIG. 7 is a vertical cross-sectional view which shows a fourth embodiment of a heating-element mounting substrate of the present invention.

FIG. 8 is a view (plan view) seen from a direction of the arrow A in FIG. 7.

FIG. 9 is a vertical cross-sectional view which shows a fifth embodiment of a heating-element mounting substrate of the present invention.

FIG. 10 is a vertical cross-sectional view which shows a metal foil-clad substrate used in Example.

FIG. 11 is a microscope photograph which shows a metal foil, a resin layer and an insulating part in a cutting plane at the vicinity of bending portions of a metal foil-clad substrate in Example.

### DETAILED DESCRIPTION OF THE INVENTION

Hereinbelow, a metal foil-clad substrate, a circuit board and a heating-element mounting substrate according to the present invention will be described in detail based on the preferred embodiments shown in the accompanying drawings.

First, prior to that description is made on the metal foil-clad substrate and the circuit board of the present invention, the description will be made on the heating-element mounting substrate according to the present invention.

In the following description, hereinafter, the description for the heating-element mounting substrate of the present invention will be made on a case that a semiconductor device including a semiconductor element as a heating element is mounted onto the circuit board.

### Heating-Element Mounting Substrate

### First Embodiment

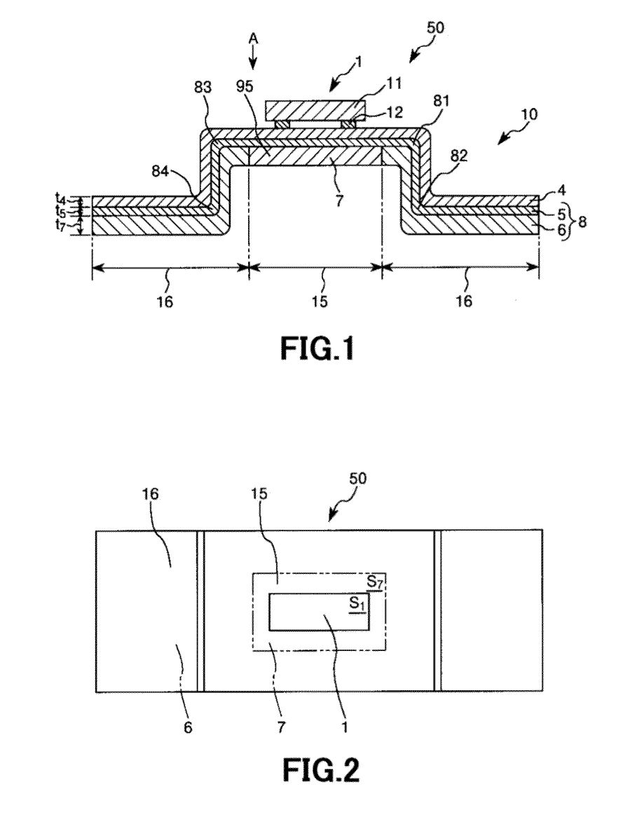

FIG. 1 is a vertical cross-sectional view which shows a first embodiment of a heating-element mounting substrate of the present invention. FIG. 2 is a view (plan view) seen from a direction of the arrow A in FIG. 1. In the following description, the upper side in FIG. 1 and the front side of the paper in FIG. 2 will be referred to as “upper”, the lower side in FIG. 1 and the back side of the paper in FIG. 2 will be referred to as “lower”, the right side in FIG. 1 will be referred to as “right” and the left side in FIG. 1 will be referred to as “left” for convenience of explanation. Further, each figure shows schematically and exaggeratingly the heating-element mounting substrate and each part thereof, so that sizes of the heating-element mounting substrate and each part thereof and a ratio therebetween are materially different from an actual product.

The heating-element mounting substrate 50 shown in FIGS. 1 and 2 includes the semiconductor device 1 which is the heating element generating heat by drive thereof and a circuit board (circuit board of the present invention) 10 to mount the semiconductor device 1. In this regard, the circuit board 10, generally, mounts another electronic component (member) such as resistances, transistors and the like other than the semiconductor device 1. However, for convenience of explanation, FIGS. 1 and 2 omit their drawings.

The semiconductor device 1 is a semiconductor package including a semiconductor element (not shown) and includes a mold part (sealing part) 11 sealing the semiconductor element (semiconductor chip) and connecting terminals 12 electrically connected with the semiconductor element (semiconductor chip).

The semiconductor element is constituted of using SiC (silicon carbide) and GaN (gallium nitride) in this embodiment. This semiconductor element generates heat by drive thereof.

The mold part 11, generally, is constituted of a cured material of various kinds of resin materials and seals the semiconductor element by surrounding the semiconductor element.

Furthermore, the connecting terminals 12 are constituted of various kinds of metal materials such as Cu, Fe, Ni, an alloy containing these metals and the like. The connecting terminals 12 are connected with terminals of the semiconductor element and terminals of a wiring 4 included in the circuit board 10, thereby electrically connecting the terminals of the semiconductor element and the terminals of the wiring 4 with each other.

The circuit board (wiring substrate) 10 includes the wiring 4 electrically connected with the semiconductor device 1 and a base material (base) 8 provided on a lower surface (surface opposite to the semiconductor device 1: one surface) of the wiring 4. The base material 8 supports the wiring 4 and is formed into a plate shape (sheet shape) in a planar view thereof.

The wiring (circuit) 4 is formed into a predetermined pattern. The terminals (not shown) formed by the pattern formation are electrically connected with the connecting terminals (terminals) 12 of the semiconductor device 1, thereby electrically connecting the terminals of the semiconductor element and the terminals of the wiring 4 with each other.

The wiring (conducting part) 4 is connected with an electronic component electrically which includes the semiconductor device 1 mounted onto the circuit board 10. The wiring 4 has a function of transferring the heat generated in the semiconductor device 1 to a side of a lower surface of the base material 8 as a heat receiving plate. The wiring 4 is formed by performing patterning of a metal foil 4A included in a metal foil-clad substrate 10A described later.

Examples of a constituent material of the wiring 4 includes various kinds of metal materials such as copper, a copper-based alloy, aluminum, an aluminum-based alloy and the like.

A thermal conductivity of the wiring 4 in a thickness direction thereof is preferably in the range of 3 to 500 W/m·K and more preferably in the range of 10 to 400 W/m·K. Such a wiring 4 has excellent thermal conductivity, so that it is possible to efficiently transfer the heat generated by the drive of the semiconductor element included in the semiconductor device 1 to the side of the base material 8 through the wiring 4.

The base material 8 include a plate-shaped (sheet-shaped) resin layer 5 in the planar view thereof and a heat radiation metal plate 7 provided on a lower surface (opposite surface) of the resin layer 5. The heat radiation metal plate 7 is arranged to correspond to a first area 15 of the lower surface of the resin layer 5 which covers an area to mount the semiconductor 1 in a planar view of the base material 8. The base material 8 further includes an insulating part 6 covering the resin layer 5 so as to correspond to a second area 16 of the lower surface of the resin layer 5 except for the first area 15.

The resin layer (bonding layer) 5 is provided on the lower surface of the wiring 4, namely between the wiring 4 and the insulating part 6 and the heat radiation metal plate 7 which are located at a lower side of the wiring 4. The wiring 4 is bonded with the insulating part 6 and the heat radiation metal plate 7 through the resin layer 5.

This rein layer 5 has insulation property. This makes it possible to ensure an insulation state between the wiring 4 and the heat radiation metal plate 7.

Furthermore, the resin layer 5 is constituted to exhibit excellent thermal conductivity. This makes it possible for the resin layer 5 to transfer the heat at the side of the semiconductor device 1 (wiring 4) to the heat radiation metal plate 7.

A thermal conductivity of the resin layer 5 is preferably high, specifically is more preferably in the range of 1 to 15 W/m·K and even more preferably in the range of 5 to 10 W/m·K. This makes it possible to efficiently transfer the heat at the side of the semiconductor device 1 to the heat radiation metal plate 7 by the resin layer 5. Therefore, it is possible to efficiently transfer the heat generated by the drive of the semiconductor element included in the semiconductor device 1 to the heat radiation metal plate 7 through the wiring 4 and the resin layer 5. As a result, it becomes possible to efficiently radiate the heat generated in the semiconductor device 1.

A thickness (average thickness) t₅ of the resin layer 5 is not limited particularly, but is preferably thinner than a thickness t₇ of the heat radiation metal plate 7 as shown in FIG. 1. Specifically, the thickness t₅ of the resin layer 5 is preferably in the range of about 50 to 250 μm and more preferably in the range of about 80 to 200 μm. This makes it possible to improve the thermal conductivity of the resin layer 5 while ensuring the insulation property of the resin layer 5.

A glass transition temperature of the resin layer 5 is preferably in the range of 100 to 200° C. This makes it possible to improve stiffness of the resin layer 5, thereby enabling warpage of the resin layer 5 to be lowered. As a result, it is possible to suppress the warpage from occurring to the circuit board 10.

In this regard, it is to be noted that the glass transition temperature of the resin layer 5 is measured based on JIS C 6481 as follows.

A dynamic viscoelastic measurement device (“DMA/983” produced by TA Instruments) is used for the measurement. A tensile load is applied to the resin layer 5 under a nitrogen atmosphere (200 ml/min). The glass transition temperature is measured under conditions of a frequency of 1 Hz, a temperature in the range of −50 to 300° C. and a rate of temperature increase of 5° C./min to obtain a chart having peaks. The glass transition temperature Tg is obtained from a tan δ peak position in the chart.

An elastic modulus (storage elastic modulus) E′ of the resin layer 5 at a temperature of 25° C. is preferably in the range of 10 to 70 GPa. This makes it possible to improve the stiffness of the resin layer 5, thereby enabling the warpage occurring to the resin layer 5 to be lowered. As a result, it is possible to suppress the warpage from occurring to the circuit board 10.

In this regard, it is to be noted that the storage elastic modulus is able to be measured with the dynamic viscoelastic measurement device. Specifically, the storage elastic modulus E′ is measured as a value of the storage elastic modulus at 25° C. when the tensile load is applied to the resin layer 5 and the storage elastic modulus is measured under the conditions of the frequency of 1 Hz, the rate of temperature increase of 5 to 10° C./min and the temperature in the range of −50 to 300° C.

The resin layer 5 having such functions is constituted so that a filler is dispersed in a layer constituted of a resin material as a main component thereof.

The resin material exhibits a function as a binder holding the filler within the resin layer 5. The filler has a higher thermal conductivity than the thermal conductivity of the resin material. With the configuration of the resin layer 5, it is possible to enhance the thermal conductivity of the resin layer 5.

Such a resin layer 5 is constituted of a cured material or a solidified material formed by curing or solidifying a resin composition for forming resin layer which includes the resin material and the filler mainly. In other words, the resin layer 5 is constituted of the cured material or the solidified material which are obtained by shaping the resin composition for forming resin layer in the form of laminae.

Hereinafter, the description will be made on this resin composition for forming resin layer.

The resin composition for forming resin layer (hereinafter, simply referred to as “second resin composition”) includes and is constituted of the resin material and the filler mainly as described above.

The resin material is not limited particularly, but includes various kinds of resin materials such as a thermoplastic resin and a thermosetting resin.

Examples of the thermoplastic resin includes: polyolefin such as polyethylene, polypropylene, an ethylene-vinylacetate copolymer; denatured polyolefin; polyamide (e.g. nylon 6, nylon 46, nylon 66, nylon 610, nylon 612, nylon 11, nylon 12, nylon 6-12, and nylon 6-66); thermoplastic polyimide; a liquid crystal polymer such as aromatic polyester; polyphenylene oxide: polyphenylene sulfide; polycarbonate; polymethyl methacrylate; polyether; polyether ether ketone; polyether imide; polyacetal; various kinds of thermoplastic elastomers such as a styrene-based elastomer, a polyolefin-based elastomer, a polyvinylchloride-based elastomer, a polyurethane-based elastomer, a polyester-based elastomer, a polyamide-based elastomer, a polybutadiene-based elastomer, a trans-polyisoprene-based elastomer, a fluororubber-based elastomer, and a chlorinated polyethylene-based elastomer; a copolymer, a blend polymer and a polymer alloy containing these polymers mainly; and the like. These polymers may be used singly or in combination of two or more of them.

On the other hand, examples of the thermosetting resin (second thermosetting resin) includes an epoxy resin, a phenol resin, an urea resin, a melamine resin, a polyester (unsaturated polyester) resin, a polyimide resin, a silicone resin, an urethane resin and the like. These resins may be used singly or in combination of two or more of them.

Among them, the resin material used for the second resin composition is preferably the thermosetting resin and more preferably the epoxy resin. This makes it possible to obtain the resin layer 5 having excellent heat resistance. Further, it is possible to firmly bond the wiring 4 to the base material 8 by the resin layer 5, thereby enabling the obtained heating-element mounting substrate 50 to exhibit excellent heat radiation (heat dissipation property) in addition to excellent durability.

Further, it is preferred that the epoxy resin includes an epoxy resin (A) having at least any one of an aromatic ring structure and an alicyclic structure (alicyclic carbon ring structure). Use of such an epoxy resin (A) makes it possible to more improve the thermal conductivity of the resin layer 5 while increasing the glass transition temperature of the resin layer 5. Further, it is possible to improve adhesion of the resin layer 5 to the wiring 4, the insulating part 6 and the heat radiation metal plate 7.

Examples of the epoxy resin (A) having the aromatic ring structure or the alicyclic structure includes; a bisphenol type epoxy resin such as a bisphenol A type epoxy resin, a bisphenol F type epoxy resin, a bisphenol S type epoxy resin, a bisphenol E type epoxy resin, a bisphenol M type epoxy resin, a bisphenol P type epoxy resin, and a bisphenol Z type epoxy resin; a novolak type epoxy resin such as a phenol novolak type epoxy resin, a cresol novolak type epoxy resin, and a tetraphenol group ethane type and novolak type epoxy resin; a biphenyl type epoxy resin; an arylalkylene type epoxy resin such as a phenol aralkyl type epoxy resin having a biphenylene skeleton; an epoxy resin such as a naphthalene type epoxy resin; and the like. These resins may be used singly or in combination of two or more of them.

It is preferred that this epoxy resin (A) is the naphthalene type epoxy resin. This makes it possible to further increase the glass transition temperature of the resin layer 5, so that it is possible to suppress voids from generating in the resin layer 5. Further, it is possible to further improve the thermal conductivity and breakdown voltage.

It this regard, it is to be noted that the naphthalene type epoxy resin means a resin having a naphthalene ring skeleton and two or more of glycidyl groups.

An amount of the naphthalene type epoxy resin included in the epoxy resin is preferably in the range of 20 to 80 mass % and more preferably in the range of 40 to 60 mass % with respect to 100 mass % of the epoxy resin.

Examples of the naphthalene type epoxy resin include resins represented by the following formulae (5) to (8).

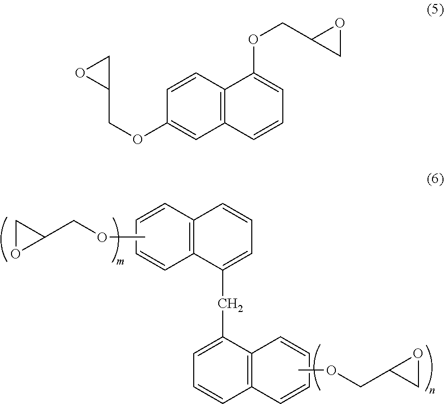

(In the formula, each of “m” and “n” represents the number of a substituent group on the naphthalene ring and independently an integer of 1 to 7.)

In this regard, it is preferred that any one or more of the following compounds are used as the compound represented by the formula (6).

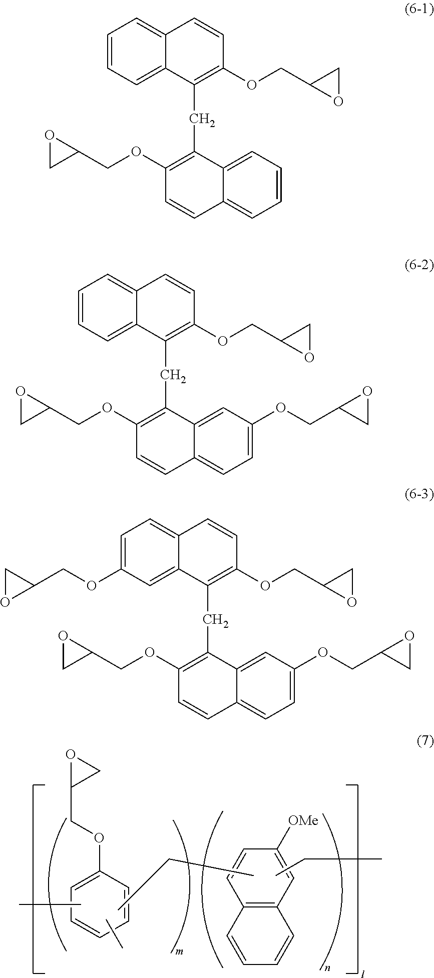

(In the formula, “Me” represents a methyl group and “l”, “m” and “n” represent an integer of 1 or more.)

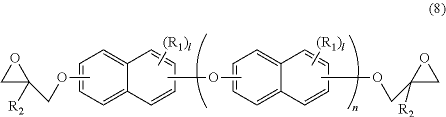

(In the formula, “n” is an integer in the range of 1 to 20, “l” is an integer of 1 or 2, each “R₁” is independently a hydrogen atom, a benzyl group, an alkyl group or the substituent group represented by the following formula (9), and each “R₂” is independently a hydrogen atom or a methyl group.)

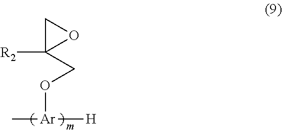

(In the formula, “Ar” is independently a phenylene group or a naphthylene group, “R₂” is independently a hydrogen atom or a methyl group, and “m” is an integer of 1 or 2.)

The naphthalene type epoxy resin in the formula (8) is classified into, as it is called, a naphthylene ether type epoxy resin. The compound represented by the formula (8) includes the compound represented by the following formula (10) as an example.

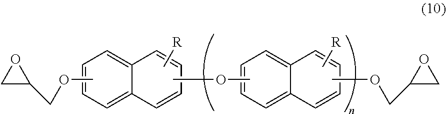

(In the above formula (10), “n” is an integer in the range of 1 to 20, preferably the integer in the range of 1 to 10, and more preferably the integer in the range of 1 to 3. Each “R” is independently a hydrogen atom or the substituent group represented by the following formula (11), preferably the hydrogen atom.)

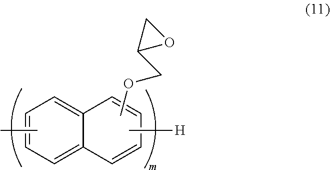

(In the above formula (11), “m” is an integer of 1 or 2.)

The naphthylene ether type epoxy resin represented by the above formula (10), specifically, includes the resins represented by the following formulae (12) to (16).

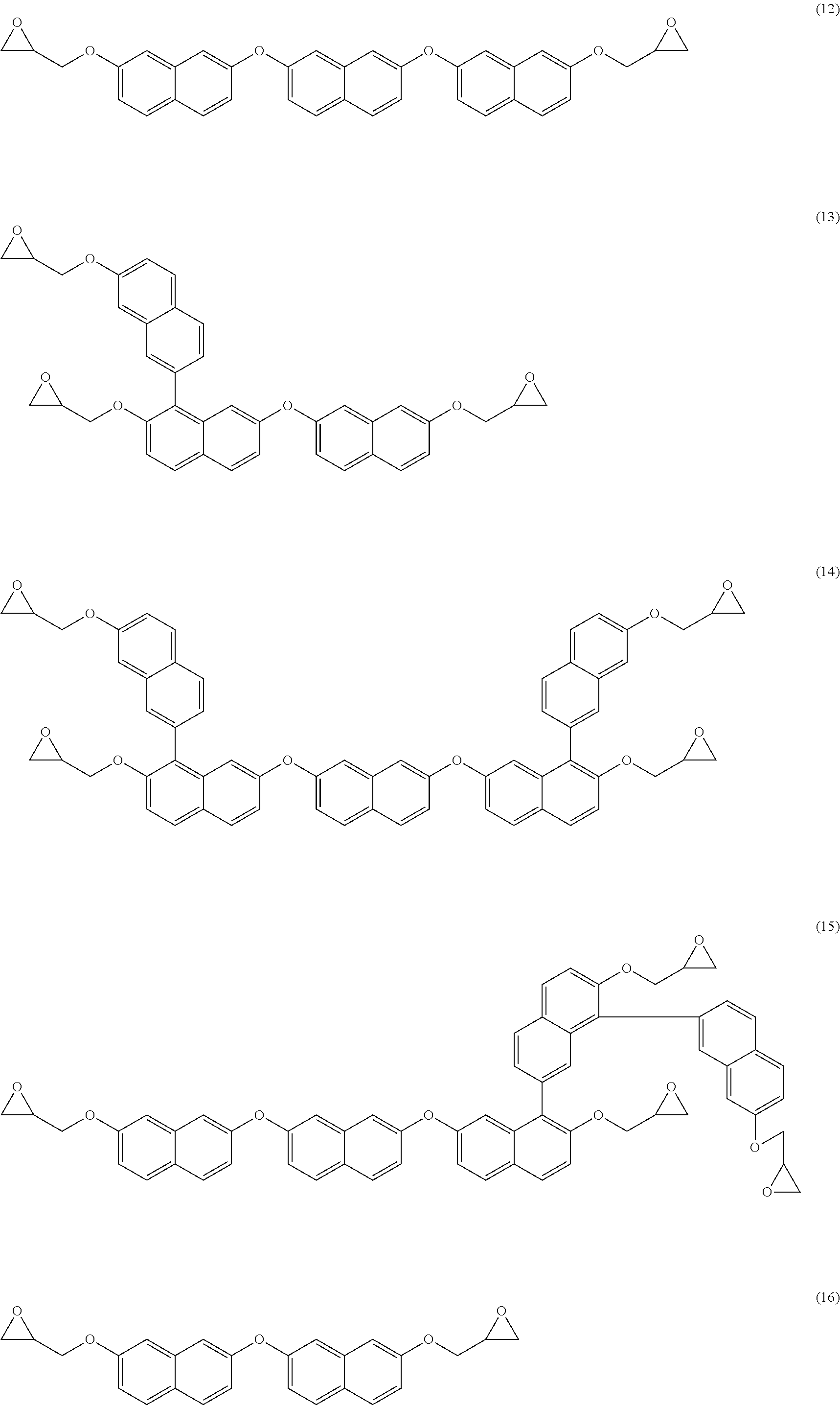 [SMILES: c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1 ; c1cc2ccc(-c3c(OCC4CO4)ccc4ccc(Oc5ccc6ccc(Oc7ccc8ccc(OCC9CO9)c(-c9ccc%10ccc(OCC%11CO%11)cc%10c9)c8c7)cc6c5)cc34)cc2cc1OCC1CO1 ; c1cc2ccc(Oc3ccc4ccc(Oc5ccc6ccc(OCC7CO7)c(-c7ccc8ccc(OCC9CO9)c(-c9ccc%10ccc(OCC%11CO%11)cc%10c9)c8c7)c6c5)cc4c3)cc2cc1OCC1CO1 ; c1cc2ccc(Oc3ccc4ccc(OCC5CO5)cc4c3)cc2cc1OCC1CO1]

An amount of the resin material is preferably in the range of 30 to 70 volume % and more preferably in the range of 40 to 60 volume % with respect to a whole amount of the second resin composition (except a solvent). This makes it possible to obtain the resin layer 5 having excellent mechanical strength and thermal conductivity. Further, it is possible to improve the adhesion of the resin layer 5 to the wiring 4, the insulating part 6 and the heat radiation metal plate 7.

In contrast, if the amount is smaller than the lower limit value noted above, depending on a kind of the resin material, there is a fear that it is impossible to sufficiently exhibit the function as the binder that the resin material bonds between the fillers, thereby lowering the mechanical strength of the obtained resin layer 5. In addition, depending on the constituent material of the second resin composition, a viscosity of the second resin composition is too high, so that it becomes difficult to carry on a filtration treatment of the second resin composition (varnish) and shape (coat) the second resin composition in the form of laminae. Further, there is a fear that a flow of the second resin composition is too slow, so that the voids generate in the resin layer 5.

On the other hand, if the amount exceeds the upper limit value noted above, depending on the kind of the resin material, there is a fear that it becomes difficult to obtain the resin layer 5 having the excellent thermal conductivity while ensuring the insulation property of the resin layer 5.

Further, in the case where the resin material includes the epoxy resin, it is preferred that a phenoxy resin is contained in the second resin composition. This makes it possible to suppress handling property of the resin layer 5 from being lowered due to a highly-filled filler because flex resistance of the resin layer 5 is improved.

Further, if the phenoxy resin is contained in the second resin composition, fluidity of the second resin composition at the time of press is lowered by the increased viscosity of the second resin composition. Since the phenoxy resin has effects of ensuring the thickness of the resin layer 5, providing with a uniform thickness thereof and suppressing the voids from generating, it is possible to more improve the insulation reliability and the thermal conductivity. In addition, improved are the adhesions between the resin layer 5 and the wiring 4 and between the heat radiation metal plate 7 and the insulating part 6. The synergetic effect of the effects makes it possible to further enhance the thermal conductivity and the insulation reliability of the heating-element mounting substrate 50.

Examples of the phenoxy resin include a phenoxy resin having a bisphenol skeleton, a phenoxy resin having a naphthalene skeleton, a phenoxy resin having an anthracene skeleton, a phenoxy resin having a biphenyl skeleton, and the like. A phenoxy resin of a structure having two or more of these skeletons can be also used.

Among them, it is preferred to use a phenoxy resin having a bisphenol A skeleton or a bisphenol F skeleton. Such a phenoxy resin may have both the bisphenol A skeleton and the bisphenol F skeleton.

Amount of the phenoxy resin is preferably in the range of 1 to 15 mass % and more preferably in the range of 2 to 10 mass % with respect to 100 mass % of a whole solid content of the second resin composition.

Depending on the kind of the resin material described above (e.g. case of the epoxy resin), a curing agent is contained in the second resin composition as necessary.

Examples of the curing agent include, but not limited thereto, an amide based curing agent such as dicyandiamide and aliphatic polyamide; an amine based curing agent such as diamino diphenyl methane, methane phenylene diamine, ammonia, triethylamine and diethylamine; a phenol based curing agent such as bisphenol A, bisphenol F, a phenol novolak resin, a cresol novolak resin and a p-xylene-novolak resin; acid anhydrides; and the like.

Further, the second resin composition may contain a curing catalyst (curing accelerator) further. This makes it possible to improve curing property of the second resin composition.

Examples of the curing catalyst include: imidazoles; an amine based catalyst such as 1,8-diazabicyclo(5,4,0)undecene; a phosphorous catalyst such as triphenylphosphine; and the like. Among them, the imidazoles are preferable. This makes it possible to obtain both rapid curing property and preserving property of the second resin composition.

Examples of the imidazoles include: 1-benzyl-2-methylimidazol, 1-benzyl-2-phenylimidazol, 1-cyanoethyl-2-ethyl-4-methylimidazol, 2-phenyl-4-methylimidazol, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, a 2,4-diamino-6-[2′-methylimidazolyl-(1′)]-ethyl-s-triazine isocyanuric acid adduct, a 2-phenylimidazol isocyanuric acid adduct, 2-phenyl-4,5-dihydroxymethylimidazol, 2-phenyl-4-methyl-5-hydroxymethylimidazol, 2,4-diamino-6-vinyl-s-triazine, a 2,4-diamino-6-vinyl-s-triazine isocyanuric acid adduct, 2,4-diamino-6-methacryloyloxyethyl-s-triazine, a 2,4-diamino-6-methacryloyloxyethyl-s-triazine isocyanuric acid adduct, and the like. Among them, 2-phenyl-4,5-dihydroxymethylimidazol or 2-phenyl-4-methyl-5-hydroxymethylimidazol is preferable. This makes it possible to improve the preserving property of the second resin composition particularly.

An amount of the curing catalyst is not limited particularly, but is preferably in the range of about 0.01 to 30 parts by mass and more preferably in the range of about 0.5 to 10 parts by mass with respect to the 100 parts by mass of the resin material. If the amount is smaller than the lower limit value noted above, there is a case that the insufficient curing property is obtained to the second resin composition. On the other hand, if the amount exceeds the upper limit value noted above, the second resin composition shows a tendency that the preserving property thereof is lowered.

An average particle size of the curing catalyst is not limited particularly, but is preferably equal to or lower than 10 μm and more preferably in the range of 1 to 5 μm. If the average particle size falls within the above range, the reactivity of the curing catalyst becomes particular excellent.

It is preferred that the second resin composition contains a coupling agent further. This makes it possible to more improve the adhesion of the resin material to the filler, the insulating part 6, the heat radiation metal plate 7 and the wiring 4.

Examples of such a coupling agent include a silane type coupling agent, a titanium type coupling agent, an aluminum type coupling agent and the like. Among them, the silane type coupling agent is preferable. This makes it possible to improve the thermal conductivity and the heat resistance of the second resin composition.

Examples of the silane type coupling agent include vinyl trichloro silane, vinyl trimethoxy silane, vinyl triethoxy silane, β-(3,4-epoxycyclohexyl)ethyl trimethoxy silane, γ-glycidoxypropyl trimethoxy silane, γ-glycidoxypropylmethyl dimethoxy silane, γ-methacryloxypropyl trimethoxy silane, γ-methacryloxypropylmethyl diethoxy silane, γ-methacryloxypropyl triethoxy silane, N-β(aminoethyl)-γ-aminopropylmethyl dimethoxy silane, N-β(aminoethyl)-γ-aminopropyl trimethoxy silane, N-β(aminoethyl)-γ-aminopropyl triethoxy silane, γ-aminopropyl trimethoxy silane, γ-aminopropyl triethoxy silane, N-phenyl-γ-aminopropyl trimethoxy silane, γ-chloropropyl trimethoxy silane, γ-mercaptopropyl trimethoxy silane, 3-isocyanatepropyl triethoxy silane, 3-acryloxypropyl trimethoxy silane, bis(3-triethoxysilyl propyl)tetrasulfane and the like.

An amount of the coupling agent is not limited particularly, but is preferably in the range of about 0.01 to 10 parts by mass and more preferably in the range of about 0.5 to 10 parts by mass with respect to the 100 parts by mass of the resin material. If the amount is smaller than the lower limit value noted above, there is a case that the effect to improve the adhesion as described above becomes insufficient. On the other hand, if the amount exceeds the upper limit value noted above, there is a case to cause outgas and voids when the resin layer 5 is formed.

The filler in the second resin composition is constituted of an inorganic material. This makes it possible for the filler to exhibit higher thermal conductivity than the thermal conductivity of the resin material. Therefore, dispersion of the filler in the second resin composition makes it possible to enhance the thermal conductivity of the resin layer 5.

Among the filler constituted of the inorganic material, the filler is preferably a granular body constituted of at least one of aluminum oxide (alumina, Al₂O₃) and aluminum nitride and more preferably a granular body constituted of the aluminum oxide mainly. This makes it possible to exhibit the excellent thermal conductivity (heat radiation) and the excellent insulation property. Further, the aluminum oxide is more preferable from the point of view of excellent versatility and a low price thereof.

Hereinafter, the description will be made on a case that the filler is the granular body constituted of aluminum oxide as a main component thereof.

An amount of the filler is preferably in the range of 30 to 70 volume % and more preferably in the range of 40 to 60 volume % with respect to the whole amount of the second resin composition (except the solvent). The high amount of the filler in the second resin composition falling within such a range makes it possible to obtain the resin layer 5 having more excellent thermal conductivity.

In contrast, if the amount is smaller than the lower limit value noted above, it is difficult to obtain the resin layer 5 having the excellent thermal conductivity while exhibiting the insulation property of the resin layer 5. On the other hand, if the amount exceeds the upper limit value noted above, depending on the constituent material of the second resin composition, the viscosity of the second resin composition is too high, so that it becomes difficult to carry on the filtration treatment of the varnish and shape (coat) the varnish in the form of laminae. Further, there is a case that the flow of the second resin composition is too slow, so that the voids generate in the obtained resin layer 5.

Even if the amount of the filler in the second resin composition is set highly to fall within the range as described above, when the viscosity of the second resin composition under conditions of the temperature of 25° C. and a shear rate of 1.0 rpm is defined as A [Pa·S], the viscosity of the second resin composition under the conditions of the temperature of 25° C. and the shear rate of 10.0 rpm is defined as B [Pa·S] as the second resin composition and the second resin composition which satisfies a relation that A/B (thixo ratio) is in the range of 1.2 to 3.0 is used, it is possible to provide with the second resin composition (varnish) having an appropriate viscosity and an appropriate flow property at the time of producing the circuit board 10 (metal foil-clad substrate 10A).

Furthermore, a moisture content of the filler is preferably in the range of 0.10 to 0.30 mass %, more preferably in the range of 0.10 to 0.25 mass %, and even more preferably in the range of 0.12 to 0.20 mass %. Even if the amount of the filler is large, the second resin composition has the more appropriate viscosity and flow property. Therefore, it is possible to form the resin layer 5 having the excellent thermal conductivity while preventing the voids from generating in the obtained resin layer 5. In other words, it is possible to form the resin layer 5 having the excellent thermal conductivity and the insulation property.

The aluminum oxide, generally, is obtained by sintering aluminum hydroxide. The granular body of the obtained aluminum oxide is constituted from a plurality of primary particles. An average particle size of the primary particles is set according to the sinter conditions.

The aluminum oxide which is subjected to no treatment after sintering is constituted from aggregates (secondary particles) in which the primary particles have adhered to and agglutinated with each other.

Therefore, the aggregates of the primary particles are broken up by pulverization, as necessary, to obtain finally the filler. An average particle size of the finally obtained filler is set according to the pulverization conditions (e.g. time).

The aluminum oxide has extremely-high hardness at the time of pulverizing. Therefore, the aggregates are simply broken up and the primary particles in themselves are not almost broken. Therefore, the average particle size of the primary particles is nearly maintained even after the pulverization.

If the pulverizing time becomes long, the average particle size of the filler approaches to the average particle size of the primary particles. Then, if the pulverizing time becomes over a predetermine time, the average particle size of the filler equals to the average particle size of the primary particles. In other words, if the pulverizing time is short, the filler is constituted of the secondary particles mainly. On the other hand, if the pulverizing time becomes long, the amount of the primary particles becomes large. If the pulverizing time becomes over the predetermine time finally, the filler is constituted of the primary particles mainly.

Further, each of the primary particles of the aluminum oxide obtained by sintering the aluminum hydroxide as described above is non-spherical and is formed into a shape having a flat surface as a scaly shape. Therefore, it is possible to increase a contact area between the fillers. As a result, it is possible to improve the thermal conductivity of the obtained resin layer 5.

Further, the filler is a mixture of three components (large particle size component, medium particle size component and small particle size component) having a different average particle size from each other. It is preferred that the large particle size component is spherical and the medium particle size component and the small particle size component are polyhedral.

Specifically, it is preferred that the filler is a mixture of a large particle size alumina, a medium particle size aluminum oxide and a small particle size aluminum oxide. An average particle size of the large particle size alumina falls within a first particle size range which is preferably in the range of 5.0 to 50 μm and more preferably in the range of 5.0 to 25 μm. A roundness of the large particle size alumina is preferably in the range of 0.80 to 1.0 and more preferably in the range of 0.85 to 0.95. An average particle size of the medium particle size aluminum oxide falls within a second particle size range which is preferably in the range of 1.0 to 5.0 μm. A roundness of the medium particle size aluminum oxide is preferably in the range of 0.50 to 0.90 and more preferably in the range of 0.70 to 0.80. An average particle size of the small particle size aluminum oxide falls within a third particle size range which is preferably in the range of 0.1 to 1.0 μm. A roundness of the small particle size aluminum oxide is preferably in the range of 0.50 to 0.90 and more preferably in the range of 0.70 to 0.80.

In this regard, the particle size of the filler is measured by using a laser diffraction type grain size distribution measuring apparatus “SALD-7000” after an aluminum oxide solution is subjected to an ultrasonic treatment for 1 minute to disperse the aluminum oxide in water.

By doing so, the medium particle size component is filled in gaps of the large particle size component and further the small particle size component is filled in gaps of the medium particle size component. Therefore, it is possible to enhance filling property of the aluminum oxide, thereby enabling a contact area between the particles of the aluminums oxide to more increase. As a result, it is possible to more improve the thermal conductivity of the resin layer 5. Furthermore, it is possible to improve the heat resistance, the flex resistance and the insulation property of the resin layer 5.

Use of such a filler makes it possible to improve the adhesions between the resin layer 5 and the wiring 4 and between the heat radiation metal plate 7 and the insulating part 6 more.

The synergetic effect of these effects makes it possible to improve the insulation reliability and the heat radiation reliability of the heating-element mounting substrate 50 more.

The second resin composition may contain an additive agent such as a leveling argent, an antifoam argent and the like in addition to the components as described above.

The second resin composition contains a solvent such as methylethyl ketone, acetone, toluene, dimethylformaldehyde and the like. The second resin composition becomes a varnish state when the resin material is dissolved in the solvent.

In this regard, the second resin composition in such a varnish state is obtained by mixing the resin material with the solvent as necessary to make the varnish state and thereafter mixing the filler therewith.

Further, examples of a mixing machine used for mixing is not limited particularly, but included a disperser, a multiple blade type agitator, a bead mill, a homogenizer and the like.

In the case where the resin material has the high thermal conductivity, the addition of the filler to the second resin composition may be omitted. In other words, the resin layer 5 may not include the filler and is constituted of the resin material mainly.

The heat radiation metal plate 7 is formed in the first area 15 of the lower surface (opposite surface) of the resin layer 5, which covers the area of the wiring 4 to mount the semiconductor device 1 in the planar view of the base material 8 (resin layer 5).

Such a heat radiation metal plate 7 functions as a member (heat radiation plate) of radiating the heat generated by the drive of the semiconductor element included in the semiconductor device 1 from the side of the lower surface of the heat radiation metal plate 7 (circuit board 10) through the wiring 4 and the resin layer 5.

Therefore, even if the semiconductor element included in the semiconductor device 1 is constituted of using SiC (silicon carbide) and GaN (gallium nitride) as this embodiment and generates, by the drive thereof, heat having higher temperature than a temperature of heat generated by the conventional Si power semiconductor device, it is possible to radiate the heat from the side of the lower surface through the heat radiation metal plate 7. Therefore, it is possible to reliably suppress or prevent the heat from adversely affecting to another electronic component to be mounted onto the circuit board 10 as well as the semiconductor element in itself.

Further, as shown in FIG. 2, a size (area S₇) of the heat radiation metal plate 7 is larger than a size (area S₁) of the semiconductor device 1 in the planar view of the base material 8 in this embodiment. In other words, the first area 15 to position the heat radiation metal plate 7 covers the area to mount the semiconductor device 1 in the planar view of the base material 8. Furthermore, each of the area to mount the semiconductor device 1 and the first area 15 to position the heat radiation metal plate 7 is formed into a rectangular shape in the planar view. In addition, their central portions are overlapped with each other. That is, the area and the first area 15 are arranged in a concentric fashion.

This makes it possible to improve a degree of freedom to design positions of the terminals of the wiring 4 at the time of determining a position of the semiconductor device 1 to be mounted with respect to the heat radiation metal plate 7. Further, since the heat radiation metal plate 7 is able to diffuse and radiate the heat from the semiconductor device 1, it is possible to assist the improvement of heat radiation efficiency by the heat radiation metal plate 7.

As shown in FIG. 1, a thickness (average thickness) t₇ of the heat radiation metal plate 7 and a thickness (average thickness) t₄ of the wiring 4 are different from each other. In other words, the thickness t₇ of the heat radiation metal plate 7 is thicker than the thickness t₄ of the wiring 4. This makes it possible to reliably assist the improvement of the heat radiation efficiency by the heat radiation metal plate 7.

The thickness t₄ is not limited particularly, but is preferably in the range of 3 to 120 μm and more preferably in the range of 5 to 70 μm. By setting the thickness of the wiring 4 to fall within such a range, it is possible to assist the improvement of the function as a heat receiving plate while ensuring conductivity to function as the wiring 4.

The thickness t₇ is not limited particularly, but is preferably in the range of 1 to 3 mm and more preferably in the range of 1.5 to 2.5 mm. By setting the thickness of the heat radiation metal plate 7 to fall within such a range, it is possible to assist the improvement of the function as the heat radiation plate.

In combination with the magnitude relation between the thicknesses of the heat radiation metal plate 7 and the wiring 4 and the covering relation (positional relation) between the area and the first area 15 as described above, the heat generated in the semiconductor device 1 is diffused in a wide range in the heat radiation metal plate 7 as much as possible until it reaches from the wiring 4 to the heat radiation metal plate 7. As a result, the heat is radiated promptly at the heat radiation metal plate 7, namely the heat radiation efficiency is improved.

Examples of a constituent material of the heat radiation metal plate 7 includes various kinds of metal materials such as copper, a copper-based alloy, aluminium, an aluminium-based alloy and the like. Among them, the constituent material of the heat radiation metal plate 7 is preferably aluminium or the aluminium-based alloy. Such metal materials have relatively high thermal conductivity, so that they assist the improvement of the heat radiation efficiency of the heat generated in the semiconductor device 1.

In the case where the heat radiation metal plate 7 is constituted of aluminium or the aluminium-based alloy and the wiring 4 is constituted of copper or the copper-based alloy, the thermal conductivity of the wiring 4 becomes higher than that of the heat radiation metal plate 7. Therefore, when the heat generated in the semiconductor device 1 is transferred to the wiring 4, the heat reaches the heat radiation metal plate 7 through the resin layer 5 promptly without diffusing in a wide range at the wiring 4. Then, the heat reached the heat radiation metal plate 7 is radiated to outside of the heat radiation metal plate 7 while diffusing in the heat radiation metal plate 7. Therefore, it is possible to further improve the heat radiation efficiency.

A thermal conductivity of the heat radiation metal plate 7 is preferably in the range of 15 to 500 W/m·K and more preferably in the range of 200 W/m·K (aluminium) to 400 W/m·K (copper).

The insulating part 6 is provided on the lower surface of the resin layer 5 and formed in a second area 16 other than the first area 15 of the lower surface of the resin layer 5 in the planar view of the base material 8. In other words, it is formed in the second area 16 of the lower surface of the resin layer 5, which the heat radiation metal plate 7 is not positioned, so as to surround the heat radiation metal plate 7.

This makes it possible to ensure the insulation property in the second area 16 of the lower surface of the base material 8 which the heat radiation metal plate 7 is not positioned. Further, strength as the whole of the base material 8 is ensured.

The insulating part 8 has an adiabatic effect, so that it becomes possible to block the heat radiated at the heat radiation metal plate 7 in the insulating part 8. Therefore, it is possible to reliably suppress or prevent from adversely affecting to another electronic component mounted onto the wiring (circuit board 10) to correspond to the second area 16 due to transferring this heat thereto.

In this regard, it is to be noted that the thickness (average thickness) t₇ of the heat radiation metal plate 7 and the thickness (average thickness) of the insulating part 6 are identical to each other as shown in FIG. 1. Consequently, a flat surface is constituted from the lower surface of the heat radiation metal plate 7 and the lower surface of the insulating par 6.

The insulating part 6 is constituted of a cured material of a resin composition for forming insulating part (hereinafter, simply referred to as “first resin composition”) which contains a thermosetting resin (first thermosetting resin) in the present invention. In this regard, it is to be noted that the first resin composition is different from the second resin composition.

The configuration of the insulating part 6 with the cured material makes it possible to obtain a low difference between thermal linear expansion coefficients of the resin layer 5 and the insulating part 6. When the semiconductor element of the semiconductor device 1 is driven, the semiconductor device 1 in itself generates the heat, so that the resin layer 5 and the insulating part 6 are heated. However, if the low difference between the thermal linear expansion coefficients is obtained, the warpage occurs between the resin layer 5 and the insulating part 6. Due to this, it is possible to reliably suppress or prevent the release therebetween from occurring.

Hereinafter, the description will be made on the first resin composition.

Examples of the thermosetting resin (first thermosetting resin) include, but not limited particularly, a resin having a triazine ring such as a phenol resin, an epoxy resin, an urea resin, and a melamine resin; an unsaturated polyester resin; a bismaleimide (BMI) resin; a polyurethane resin; a diallyl phthalate resin; a silicone resin; a resin having a benzoxazine ring; a cyanate ester resin and the like. These resins are used in solely or combination of 2 or more of the above resins. Among them, the phenol resin has good fluidity. Therefore, it is possible to reliably improve the fluidity of the good resin composition, thereby enabling the insulating part 6 to be formed to surround the heat radiation metal plate 7 in the planar view of the base material 8 without depending on the shape of the heat radiation metal plate 7. Further, it is possible to improve the adhesion of the insulating part 6 to the resin layer 5 and the heat radiation metal plate 7.

Examples of the phenol resin include: a novolak type phenol resin such as a phenol novolak resin, a cresol novolak resin, a bisphenol A novolak resin and an arylalkylene type novolak resin; a resol type phenol resin such as a non-denatured resol phenol resin (e.g. a dimethyleneether type resol resin and a methylol type resol resin) and an oil-denatured resol phenol resin denatured with oil (e.g. wood oil, linseed oil or walnut oil); and the like.

In the case where the novolak type phenol resin is used, a curing agent is contained in the first resin composition. Generally, hexamethylenetetramine is used as the curing agent. Furthermore, in the case where hexamethylenetetramine is used, an amount thereof is not limited particularly, but is preferably in the range of 10 to 30 parts by weight and more preferably in the range of 15 to 20 parts by weight with respect to the 100 parts by weight of the novolak type phenol resin. If the amount of the hexamethylenetetramine falls within the above range, it is possible to obtain good mechanical strength and a good molding shrinkage amount of the cured material of the first resin composition, namely the insulating part 6.

Among such phenol resins, it is preferred that resol type phenol resin is used. In the case where the novolak type phenol resin is used as a main component thereof, generally, the hexamethylenetetramine is used as the curing agent as described above, so that corrosive gas such as ammonia gas generates at the time of curing the novolak type phenol resin. Therefore, due to this, there is a fear that the heat radiation metal plate 7 is likely to be corroded. For this reason, it is preferred that the resol type phenol resin is used as compared with the novolak type phenol resin.

Further, the resol type phenol resin and the novolak type phenol resin may be used together. This makes it possible to enhance the strength as well as toughness of the insulating part 6.

Examples of the epoxy resin include: a bisphenol type epoxy resin such as a bisphenol A type epoxy resin, a bisphenol F type epoxy resin and a bisphenol AD type epoxy resin; a novolak type epoxy resin such as a phenol novolak type epoxy resin and a cresol novolak type epoxy resin; a brominated type epoxy resin such as a brominated bisphenol A type epoxy resin and a brominated phenol novolak type epoxy resin; a biphenyl type epoxy resin; a naphthalene type epoxy resin; a tris(hydroxyphenyl)methane type epoxy resin; and the like. Among them, the bisphenol A type epoxy resin, the phenol novolak type epoxy resin and the cresol novolak type epoxy resin are preferable because of having a relatively low molecular weight. This makes it possible to further improve workability and formability (moldability) at the time of forming the insulating part 6. Further, from the point of view of the heat resistance of the insulating part 6, the phenol novolak type epoxy resin, the cresol novolak type epoxy resin and the tris(hydroxyphenyl)methane type epoxy resin are preferable, in particular, the tris(hydroxyphenyl)methane type epoxy resin is more preferable.

In the case where the tris(hydroxyphenyl)methane type epoxy resin is used, a number average molecular weight thereof is not limited particularly, but is preferably in the range of 500 to 2000 and more preferably in the range of 700 to 1400.

In the case where the epoxy resin is used, it is preferred that the curing agent is contained in the first resin composition. Examples of the curing agent include, but not limited particularly, an amine compound such as aliphatic polyamine, aromatic polyamine and diamine diamide; acid anhydride such alycyclic acid anhydride and aromatic acid anhydride; a polyphenol compound such as a novolak type phenol resin; an imidazole compound; and the like. Among them, the novolak type phenol resin is preferable. This makes it possible to improve the workability and handling property of the first resin composition. It is possible to obtain excellent first resin composition from the point of view of environment.

Particularly, in the case where the phenol novolak type epoxy resin, the cresol novolak type epoxy resin and the tris(hydroxyphenyl)methane type epoxy resin are used as the epoxy resin, it is preferred that the novolak type epoxy resin is used as the curing agent. This makes it possible to improve the heat resistance of the cured material obtained from the first resin composition. In this regard, an amount of adding the curing agent to the first resin composition is not limited particularly, but is preferably within ±10 weight % to an acceptable range from a theory equivalent ratio of 1.0 with respect to the epoxy resin.

Further, the first resin composition may contain a curing accelerator with the curing agent as necessary. Examples of the curing accelerator include, but not limited particularly, an imidazole compound, a tertiary amine compound, an organic phosphorous compound and the like. An amount of the curing accelerator is not limited particularly, but in the range of 0.1 to 10 parts by weight and more preferably in the range of 3 to 8 parts by weight with respect to the 100 parts by weight of the epoxy resin.

Further, it is preferred that the first resin composition contains a fiber reinforcement material which functions as the filler. This makes it possible for the insulating part 6 in itself to exhibit excellent stiffness and excellent mechanical strength.

Examples of the fiber reinforcement material include, but not limited particularly, a glass fiber; a carbon fiber; a plastic fiber such as an aramid fiber (aromatic polyamide), a poly-p-phenylenebenzobisoxazol (PBO) fiber, a polyvinylalcohol (PVA) fiber, a polyethylene (PE) fiber and a polyimide fiber; an inorganic fiber such as a basalt fiber; a metal fiber such as a stainless fiber; and the like. One or more of these fibers may be used independently or in combination.

Furthermore, for a purpose of improving the adhesion between the thermosetting resin and the fiber reinforcement material, the fiber reinforcement material may be subjected to a surface treatment with a silane coupling agent. Examples of such a silane coupling agent include, but not limited particularly, an amino silane coupling agent, an epoxy silane coupling agent, a vinylsilane coupling agent and the like. One or more of these agents may be used independently or in combination.

Among these fiber reinforcement materials, it is preferred that the carbon fiber or the aramid fiber is used. This makes it possible to further improve the mechanical strength of the insulating part 6. In particular, use of the carbon fiber makes it possible to more improve wear resistance of highly-loaded insulating part 6. In this regard, from the point of view of assisting the further reduction in size of the insulating part 6, it is preferred that the fiber reinforcement material is the plastic fiber such as the aramid fiber. In addition, from the point of view of improving the mechanical strength of the insulating part 6, it is preferred that a fiber base material such as the glass fiber or the carbon fiber is used as the fiber reinforcement material.

An amount of the fiber reinforcement material in the cured material is preferably equal to or more than 10 volume %, more preferably equal to or more than 20 volume % and even more preferably equal to or more than 25 volume % with respect to a total amount of the cured material. Further, an upper limit value of the amount of the fiber reinforcement material with respect to the total amount of the cured material is not limited particularly, but is preferably equal to or lower than 80 volume %. This makes it possible to reliably improve the mechanical strength of the insulating part 6.

Furthermore, the first resin composition may contain a material other than the fiber reinforcement material as the filler. Such a filler may be any one of an inorganic filler and an organic filler.

Examples of the inorganic filler include titanium oxide, zirconium oxide, silica, calcium carbonate, boron carbide, cray, mica, talc, wallastonite, glass beads, mild carbon, graphite, and the like. In particular, it is preferred the inorganic filler includes a metal oxide such as titanium oxide, zirconium oxide, and silica. This makes it possible for an oxide film of the metal oxide to exhibit a function as a passive film and improve acid resistance as the whole of the cured material.

Examples of the organic filler include polyvinyl butyral, an acrylonitrilebutadiene rubber (NBR), pulp, wood flour and the like. In this regard, the acrylonitrilebutadiene rubber may be any one of a type having a partial cross-linked structure or a type having a carboxy-modified structure. Among them, from the point of view of further improving the effect to improve the toughness of the cured material, the acrylonitrilebutadiene rubber is preferable.

In the regard, the first resin composition may contain an additive such as a release agent, a curing auxiliary agent, a pigment and the like other than the components described above.

It is preferred that the filler contained in the resin layer 5 disperses to the side of the insulating part 6 in the resin layer 5 at the vicinity of an interface between the insulating part 6 and the resin layer 5. By doing so, as if a mixing state of the resin layer 5 and the insulating part 6 is made at the vicinity of the interface between the insulating part 6 and the resin layer 5, it is possible to assist the improvement of the adhesion between the insulating part 6 and the resin layer 5. Therefore, it is possible for the heating-element mounting substrate 50 to exhibit excellent durability.

The circuit board 10 having such a configuration is constituted from a laminated body in which the insulating part 6, the resin layer 5 and the wiring 4 are laminated from the side of the lower surface thereof in this order in the second area 16. As shown in FIG. 1, the laminated body has four bending portions 81 to 84 which are bended to the side of the upper surface (side of the wiring 4) or the side of the lower surface (side of the insulating part 6).

In other words, the circuit board 10 of the present embodiment has two bending portions 81 and 82 in a planar direction of the right side of the circuit board 10 getting away from the first area 15 (the heat radiation metal plate 7). Among them, the bending portion 81 is bended to the side of the lower surface of the insulating part 6 and the bending portion 82 is bended to the side of the upper surface of the wiring 4. Consequently, the two bending portions 81 and 82 are bended in an opposite direction to each other. Furthermore, the circuit board 10 of the present embodiment has two bending portions 83 and 84 in the planar direction of the left side of the circuit board 10 getting away from the first area 15 (the heat radiation metal plate 7). Among them, the bending portion 83 is bended to the side of the lower surface of the insulating part 6 and the bending portion 84 is bended to the side of the upper surface of the wiring 4. Consequently, the two bending portions 83 and 84 are bended in the opposite direction to each other. If the circuit board 10 provides with such bending portions 81 to 84, the heat radiation metal plate 7 positioned in the second area 15 is arranged on a convex portion 95 protruding from the whole of the circuit board 10 in a thickness direction of the base material 8.

As described above, if the wiring 4, the resin layer 5 and the insulating part 6 have the bending portions 81 to 84 which are bended to the side of the upper surface of the wiring 4 or the side of the lower surface of the insulating part 6 in the second area 16, the circuit board 10 has a steric shape (structure). Therefore, it is possible to assist the reduction in size of the circuit board 10 and design a whole shape of the circuit board 10 to correspond to a space in which the circuit board 10 is to be arranged. As a result, a degree of freedom to design the circuit board 10 is improved. Therefore, it is possible to mount the circuit board 10 onto another structure without giving any limitation to a whole shape of another structure to be mounted.

In this preset embodiment, a top (top portion) of each of the bending portions 81 to 84 is constituted from a curved surface. In other words, the upper surface and the lower surface of the circuit board 10 are formed by alternately connecting a flat surface and the curved surface constituting the bending portions, respectively. By doing so, even if locally-applied stress occurs to the bending portions 81 to 84 in the circuit board 10, it is possible to reliably suppress the stress from being concentrated to the top. Therefore, the improvement of the strength of each of the bending portions 81 to 84 is assisted. Therefore, it is possible to reliably reduce generation of cracking and the like in the bending portions 81 to 84. In addition, it is possible to reliably suppress or prevent peeling from generating at the blending portions 81 to 84 in the interfaces among the wiring 4, the resin layer 5 and the insulating part 6.

Furthermore, in each of the bending portions 81 to 84, a curvature radius of the curved surface is preferably equal to or more than 0.05 mm and more preferably in the range of 0.07 to 1.0 mm. This makes it possible to more conspicuously exhibit the effects obtained by setting the top to the curved surface while preventing the bending portions 81 to 84 from growing in size more than necessary.

In this regard, in each of the bending portions 81 to 84 of the present embodiment, the wiring 4, the resin layer 5 and the insulating part 6 are bended at an angle of 90° to the side of the upper surface of the wiring 4 or the side of the lower surface of the insulating part 6. The angle is not limited to 90°, but is preferably in the range of 5 to 175° and more preferably in the range of 60 to 120°. This makes it possible to more conspicuously exhibit the effects obtained when the circuit board 10 has the steric shape.

As described above, the heating-element mounting substrate 50 shown in FIG. 1, in which the semiconductor device 1 as the heating element is mounted, is obtained by mounting the semiconductor device 1 onto the circuit board 10. Further, the circuit board 10 is obtained by using the metal foil-clad substrate 10A in which the plate-shaped (sheet-shaped) metal foil 4A is provided on the upper surface (other surface) of the base material 8 instead of the wiring 4, the resin layer 5 and the insulating parts 6 described above. Such a metal foil-clad substrate 10A is produced by a method of producing the metal foil-clad substrate 10A as shown in the following.

(Method of Producing Metal Foil-Clad Substrate)

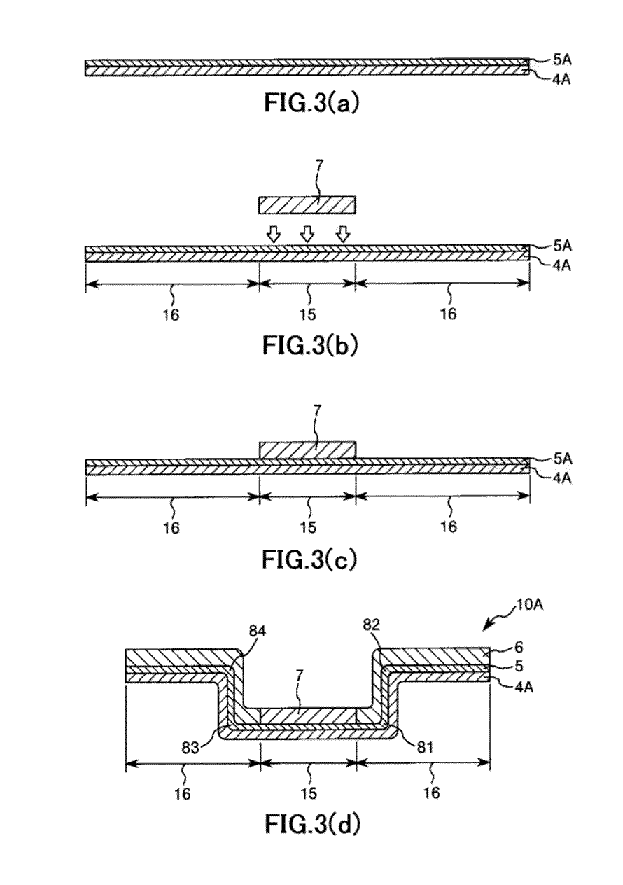

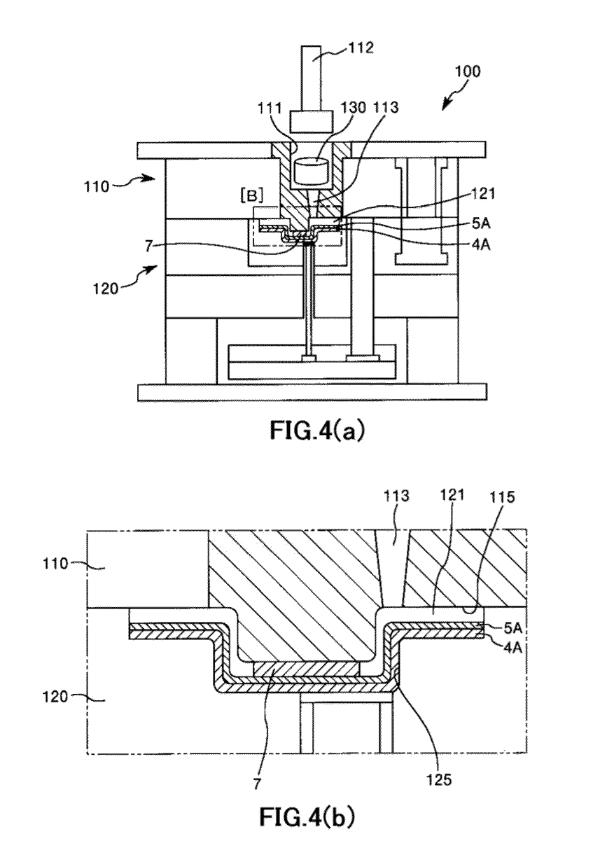

Each of FIGS. 3(a) to 3(d), 4(a) and 4(b) is a view to illustrate a method of producing a metal foil-clad substrate used for producing the heating-element mounting substrate of FIG. 1. In this regard, FIG. 4(a) is a cross-sectional view of a mold used in the method of producing the metal foil-clad substrate. FIG. 4(b) is an enlarged cross-sectional view of an area “B” surrounded by a dot-and dash line in FIG. 4(a). In the following description, the upper side in each of FIGS. 3(a) to 3(d), 4(a) and 4(b) will be referred to as “upper”, and the lower side thereof will be referred to as “lower”” for convenience of explanation. Further, FIGS. 3(a) to 3(d), 4(a) and 4(b) show schematically and exaggeratingly the metal foil-clad substrate and each part thereof, so that sizes of the metal foil-clad substrate and each part thereof and a ratio therebetween are materially different from an actual product.

[1] First, the plate-shaped metal foil 4A is prepared. Thereafter, a layer for forming resin layer (hereinafter, simply referred to as “layer”) 5A is formed on the metal foil 4A as shown in FIG. 3(a).

After the second resin composition in the varnish state described above is supplied onto the metal foil 4A in the form of laminae, this layer 5A is obtained by drying the second resin composition. Next, when the following step [2] and the step [3] are undergone, the layer 5A is changed to the resin layer 5 by curing or solidifying it.

The second resin composition is supplied onto the metal foil 4A by using a comma coater, a die coater, a gravure coater and the like.

It is preferred that the second resin composition has viscosity behavior as follows.

Specifically, when a temperature has been risen under conditions of an initial temperature of 60° C., a rate of temperature increase of 3° C./min, and a frequency of 1 Hz with the dynamic viscoelastic measurement device until the second resin composition is changed to a melt state, the viscosity behavior is an behavior that a melt viscosity decreases in an initial stage of temperature increase and the melt viscosity increases after the melt viscosity reaches to a minimum melt viscosity. Such a minimum melt viscosity is preferably in the range of 1×10³ to 1×10⁵ Pa·s.

If the minimum melt viscosity exceeds the lower limit value noted above, the resin material is separated with the filler, thereby enabling to prevent only the resin material from flowing. By undergoing the step [2] and the step [3], it is possible to obtain the more homogenous resin layer 5. On the other hand, the minimum melt viscosity is smaller than the upper limit value noted above, wetting property of the second resin composition to the metal foil 4A is improved, so that it is possible to more reliably improve the adhesion between the resin layer 5 and the metal foil 4A.

The synergetic effect of the effects makes it possible to more reliably improve the heat radiation and the breakdown voltage of the metal foil-clad substrate 10A (circuit board 10).

Further, in the second resin composition, a temperature to reach the minimum melt viscosity is preferably in the range of 60 to 100° C. and more preferably in the range of 75 to 90° C.

Furthermore, it is preferred that a flow rate of the second resin composition is in the range of 15 to 60% and more preferably in the range of 25 to 50%.

In this regard, it is to be noted that this flow rate is measured by the following processes. First, the metal foil having the resin layer formed by the second resin composition of the present embodiment is cut in a predetermined size (50 mm×50 mm). Thereafter, the cut 5 to 7 metal foils are laminated to obtain a laminated body. Next, a weight of the laminated body (weight before measurement) is measured. Next, the laminated body is pressed between heat boards of which internal temperature is hold at 175° C. for 5 minutes. Thereafter, the pressed laminated body is cooled. A resin discharged from the pressed laminated body is removed carefully to measure a weight of the cooled laminated body (weight after measurement) again. The flow rate is calculated by the following expression (I).

Flow Rate (%)=(weight before measurement-weight after measurement)/(weight before measurement-weight of metal foil) (I)

If the second resin composition has such a viscosity behavior, when the resin layer 5 is formed by heating and curing the second resin composition, it is possible to suppress air from penetrating in the second resin composition. Further, it is possible to sufficiently discharge the air dissolving in the second resin composition to the outside thereof. As a result, it is possible to suppress bubbles from generating in the resin layer 5, thereby enabling heat to reliably be transferred from the metal foil 4A to the resin layer 5. Further, by suppressing the bubbles from generating, it is possible to improve the insulation reliability of the metal foil-clad substrate 10A (circuit board 10). In addition, the adhesion between the resin layer 5 and the metal foil 4A is improved.

The synergetic effect of the effects makes it possible to more reliably improve the heat radiation of the metal foil-clad substrate 10A (circuit board 10). Consequently, it is possible to more reliably improve heat cycle characteristics of the metal foil-clad substrate 10A.

The second resin composition having such a viscosity behavior is obtained by appropriately adjusting, for example, a kind or the amount of the resin material, a kind or the amount of the filler, or a kind or an amount of a resin material in which the resin material contains the phenoxy resin. In particular, if the resin having the good fluidity such as a naphthalene type epoxy resin and the like is used as the epoxy resin, it becomes easy to obtain the viscosity characteristics as described above.

[2] Next, the heat radiation metal plate 7 is prepared. Then, as shown in FIG. 3(b), the metal foil 4A and the heat radiation metal plate 7 are pressed and heated so as to approach each other through the layer 5A.

Thus, the layer 5A and the heat radiation metal plate 7 are bonded together to correspond to the first area 15 (see FIG. 3(c)).

At this time, in the case where the layer 5A has the thermosetting property, it is preferred that the layer 5A is heated and pressed under the conditions preferably of uncuring or semi-curing and more preferably of semi-curing. On the other hand, in the case where the layer 5A has the thermoplastic property, after the layer 5A is heated and pressed to melt it, the layer 5A is heated and pressed under the condition of curing with cooling.

Heating and pressing conditions are slightly different by depending on a kind of the second resin composition included in the layer 5A, but is set as follows.

A heating temperature is set to preferably the range of about 80 to 200° C. and more preferably the range of about 170 to 190° C.

A pressure to press is set to preferably the range of about 0.1 to 3 MPa and more preferably the range of about 0.5 to 2 MPa.

A heating and pressing time is preferably for a length of time from about 10 to 90 minutes and more preferably for a length of time from about 30 to 60 minutes.

Thus, the lower surface of the heat radiation metal plate 7 is bonded together the layer 5A, so that the heat radiation metal plate 7 is bonded with the layer 5A.

In the case where the layer 5A has the thermosetting property, the process that the layer 5A is uncured or semi-cured is performed as follows. For example, in this step [2], the layer 5A is changed to a semi-cured state at the time of giving priority to bonding (attaching) the heat radiation metal plate 7 with the layer 5A. On the other hand, in the next step [3], the layer 5A is changed to an uncured state at the time of giving priority to the improvement of the adhesion in the interface between the resin layer 5 and the insulating part 6.

[3] Next, the insulating part 6 is formed on the layer 5A so as to surround the heat radiation metal plate 7 in the planar view of the layer 5A.

That is, the insulating part 6 is formed so as to cover the second area 16 of the lower surface of the layer 5A which the heat radiation metal plate 7 is not positioned.

At that time, in the case where the layer 5A has thermosetting property, the resin layer 5 is formed by curing the layer 5A. On the other hand, in the case where the layer 5A has thermoplastic property, the resin layer 5 is formed by melting the layer 5A and then solidifying it again.

Furthermore, in the second area 16, the metal foil-clad substrate 10A obtained in this step [3] is constituted from a laminated body in which the insulating part 6, the resin layer 5 and the metal foil 4A are laminated from the side of the upper surface thereof in this order. The four bending portions 81 to 84 which are bended to the side of the upper surface of the wiring 4 or the side of the lower surface of the insulating part 6 are formed in this laminated body (see FIG. 3(d)).

Examples of a method of forming the insulating part 6 include, but not limited particularly, a method in which the first resin composition is supplied to the side of the upper surface of the layer 5A so as to cover the second area 16 of the upper surface of the layer 5A, in which the heat radiation metal plate 7 is not positioned, in a state of melting the first resin composition (melting state), and thereafter the first resin composition in the melting state is shaped. Such a method makes it possible to regioselectively form the insulating part 6 with excellent accuracy to the second area 6 of the upper surface of the layer 5A.

In this regard, the four bending portions 81 to 84 are formed by supplying the first resin composition in the melting state onto the layer 5A in a state that the layer 5A and the metal foil 4A are bended at the positions to form the four bending portions 81 to 84.

Hereinafter, the description will be made on a case that the insulating part 6 is formed by such a method. In this regard, the first resin composition is formed into any shape of a granular shape (pellet shape), a sheet shape, a strip shape or a tablet shape. Hereinafter, the description will be made on a case that the first resin composition formed into the tablet shape is used as a one example.

[3-1] First, the heat radiation metal plate on which the layer 5A is formed is placed into a cavity (accommodation space) 121 formed by overlapping an upper mold 110 and a lower mold 120 of a mold 100 with each other so that the heat radiation metal plate bonded on the layer 5A faces the upper side. Thereafter, a mold clamping is performed between the upper mold 110 and the lower mold 120.

At that time, an upper surface 125 of the lower mold 120 constituting the cavity 121 has a concave portion at a side of a central portion thereof to correspond to a shape of the metal foil 4A of the metal foil-clad substrate 10A to be formed so that the bending portions 81 to 84 are formed. Further, a lower surface 115 of the upper mold 110 constituting the cavity 121 has a convex portion at a side of a central portion thereof to correspond to a shape of the insulating part 6 of the metal foil-clad substrate 10A to be formed so that the bending portions 81 to 84 are formed. This makes it possible to place the layer 5A and the metal foil 4A into the cavity 121 in a state that the bending portions 84 to 84 are bended at the positions to be formed so that the heat radiation metal plate 7 faces the upper side. Furthermore, it is possible to form the insulating part 6 formed in the later step to have the bending portions 81 to 84.

Furthermore, each of the layer 5A and the metal foil 4A is constituted of the constituent material as described above. Further, in the case where the layer 5A has the thermosetting property, the layer 5A is preferably formed in an uncured state or a semi-cured state. Therefore, the layer 5A has flexibility (flexible property). Therefore, it is possible to bend the layer 5A and the metal foil 4A at the positions to form the bending portions 84 to 84. Thus, it is possible to obtain the metal foil-clad substrate 10A in which the metal foil 4, the resin layer 5 and the insulating part 6 are bended at the bending portions 84 to 84 in the later step [3-3].

In order that the layer 5A and the metal foil 4A has the flexibility as described above, in particular, it is required to let the layer 5A have the excellent flexibility. In this case, a weight average molecular weight of each of the thermoplastic resin and the thermosetting resin used for the resin material contained in the second resin composition is preferably in the range of 1.0×10⁴ to 1.0×10⁵ and more preferably in the range of 3.0×10⁴ to 8.0×10⁴. This makes it possible to let the layer 5A have the excellent flexibility. Even if the layer 5A is bended at the positions to form the bending portions 84 to 84, it is possible to suppress or prevent cracking from occurring to the resin layer 5 at the positions. As a result, it is possible to reliably suppress or prevent a part of the layer 5A from dropping off the cracking, as it is called dusting from generating. In addition, it is possible to reliably suppress or prevent the cracking from occurring to the layer 5A.

In this regard, the weight average molecular weight of each of the thermoplastic resin and the thermosetting resin is measured with a gel permeation chromatography (GPC).

From such a point of view, it is preferred that a molecular skeleton of each of the thermoplastic resin and the thermosetting resin is formed into a straight-chain shape. The molecular skeleton formed into the straight-chain shape makes it possible to exhibit the excellent flexibility to the layer 5A. Therefore, in the case where the resin material includes the thermosetting resin, it is preferred that the thermosetting resin includes a phenoxy resin having the molecular skeleton formed into the straight-chain shape particularly.

When the mold clamping, the heat radiation metal plate 7 formed on the layer 5A is placed into the cavity 121 so that a lower side opening of a supply path 113 and the heat radiation metal plate 7 are not overlapped with each other in a thickness direction of the heat radiation metal plate 7 and the convex portion of the lower surface 115 of the upper mold 110 and the upper surface of the heat radiation metal plate 7 are in contact with each other. Thus, the insulating part 6 is formed in the later step so that the thickness of the insulating part 6 becomes identical to the thickness of the heat radiation metal plate 7. In other words, it is possible to selectively provide the insulating part 6 in the second area 16 of the upper surface of the layer 5A so that a flat surface is constituted from the upper surface of the insulating part 6 and the upper surface of the heat radiation metal plate 7 without the formation of the insulating part 6 onto the upper surface of the heat radiation metal plate 7.

The first resin composition 130 formed into the tablet shape is placed in a pot 111 of the upper mold 110.

[3-2] Next, a plunger 112 is inserted into the pot 111 while heating the mold 100 and melting the first resin composition 130 in the pot 111. Next, the first resin composition 130 is pressed.

By doing so, the first resin composition 130 in the melting state is introduced into the cavity 121 through the supply path 113.

[3-3] Next, the molten first resin composition 130 is filled into the cavity 121 so as to cover the layer 5A positioned in the second area 16 by inserting the plunger 112 into the pot 111 in a state of heating and pressing the metal foil 4A placed in the cavity 121.

At that time, an internal shape of the cavity 121 corresponds to the shape of the metal foil-clad substrate 10A to be formed since the upper surface 125 of the lower mold 120 has the concave portion at the side of the central portion thereof and the lower surface 115 of the upper mold 110 has the convex portion at the side of the central portion thereof. Therefore, the first resin composition 130 is filled into the cavity 121 so as to correspond to the shape of the insulating part 6 to be formed, namely in a state of being bended at the positions to form the bending portions 84 to 84.

Finally, the insulating part 6 is formed by curing the molten first resin composition. This makes it possible to form the insulating part 6 in the state that the insulating part 6 is bended at the bending portions 81 to 84 and surrounds the heat radiation metal plate 7 in the planar view of the layer 5A.

In the case where the layer 5A has the thermosetting property, the resin layer 5 is formed by curing the layer 5A due to this heating and pressing. In the case where the layer 5A has the thermoplastic property, the resin layer 5 is formed by melting the layer 5A, cooling the layer 5A and solidifying it again.

Heating and pressing conditions in this step are not limited particularly, but is set as follows.

A heating temperature is set to preferably the range of about 80 to 200° C. and more preferably the range of about 170 to 190° C.

A pressure to press is set to preferably the range of about 2 to 10 MPa and more preferably the range of about 3 to 7 MPa.

A heating and pressing time is preferably for a length of time from about 1 to 60 minutes and more preferably for a length of time from about 3 to 15 minutes.

By setting the heating temperature, the pressure and the heating and pressing time to fall within the above ranges, the resin layer 5 and the insulating part 6 are formed in a state that the filler contained in the resin layer 5 is dispersed to the side of the insulating part 6 in the resin layer 5 at the vicinity of the interface between the resin layer 5 and the insulating part 6 to thereby mix the resin layer 5 and the insulating part 6 apparently. Therefore, it is possible to improve the adhesion between the resin layer 5 and the insulating part 6.

A melt viscosity of the first resin composition 130 is preferably in the range of about 10 to 3000 Pa·s and more preferably in the range of 30 to 2000 Pa·s at a temperature of 175° C. This makes it possible to reliably form the insulating part 6 so as to surround the heat radiation metal plate 7 in the planar view of the resin layer 5.

The melt viscosity at the temperature of 175° C. is measured with a thermal hydraulics evaluation device (flow tester) produced by Shimadzu Corporation.

It is preferred that the metal foil 4A is pressed to a bottom surface of the cavity 121 (which is provided with the lower mold 120) by the pressure which is generated by inserting the plunger 112 into the pot 111. This makes it possible to prevent the molten first resin composition 130 from wrapping around the lower surface of the metal foil 4A. As a result, it is possible to reliably prevent the insulating part 6 from being formed to the lower surface of the metal foil 4A. Therefore, it is possible to prevent the wiring 4 obtained by performing the patterning of the metal foil 4A from being covered with the insulating part 6, so that it is possible to prevent the electrical connection between the electronic component including the semiconductor device 1 and the wiring 4 from being blocked.

The metal foil-clad substrate 10A is produced through the steps as described above.

The wiring 4 having the terminals to be electrically connected to the connecting terminals 12 of the semiconductor device 1 is formed by performing the patterning of the metal foil 4A of the metal foil-clad substrate 10A. Thus, the circuit board 10 in which the wiring 4 is formed on the base material 8 is produced. In this regard, examples of a patterning method of the metal foil 4A include, but not limited particularly, the following method. First, a resist layer corresponding to a pattern (shape) of the wiring to be formed is formed on the metal foil 4A. Thereafter, this resist layer is used as a mask and the metal foil 4A exposed from openings of the resist layer is etched by a wet etching method or a dry etching method.

In this embodiment, the description has been made on the case that one metal foil-clad substrate 10A is obtained by undergoing the above steps [3-1] to [3-3]. However, the present invention is not limited to the case. For example, a plurality of metal foil-clad substrates 10A may be obtained by placing the laminated body, in which a plurality of heat radiation metal plate 7 is formed onto the layer 5A, into the cavity 121 in the step [3-1], and then cutting the one metal foil-clad substrate 10A obtained by undergoing the above steps [3-2] and [3-3] in a thickness direction thereof. In this regard, the cutting may be performed at any stage of (I) after the step [3-3], (II) after a plurality of wirings 4 is formed on the base material 8 by performing the patterning of the metal foil 4A, or (III) after a plurality of semiconductor devices 1 is mounted onto the circuit board 10 to correspond to the plurality of wirings 4, respectively. It is preferred that the cutting is performed at the stage of (III). This makes it possible to produce a plurality of heating-element mounting substrates 50 at one time.

Further, in the present embodiment, the step [2] and the step [3] are performed as a different step. However, the present invention is not limited thereto. For example, if it is possible to press the heat radiation metal plate 7 to the metal foil 4A by inserting the plunger 112 into the pot 111 in a state that the first resin composition 130 is not filled into the pot 111, the step [2] and the step [3] may be performed in the cavity 121 on at one time.

The heating-element mounting substrates 50 having such a configuration is mounted to various kinds of electronic devices as a substrate (a component) thereof.

### Second Embodiment

Next, description will be made on a second embodiment of a heating-element mounting substrates of the present invention.

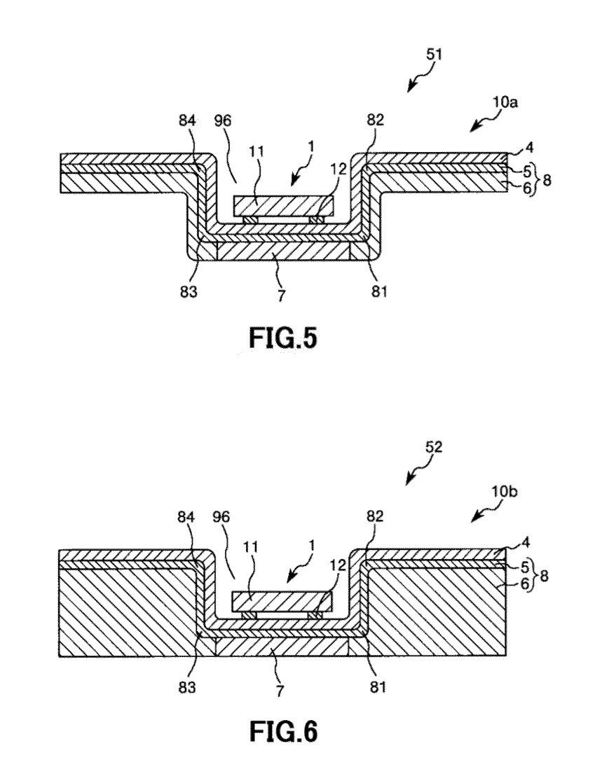

FIG. 5 is a vertical cross-sectional view which shows a second embodiment of a heating-element mounting substrate of the present invention.

Hereinafter, a heating-element mounting substrate 51 of the second embodiment will be described by focusing differences between the heating-element mounting substrate 50 of the first embodiment and that of the second embodiment, and description of the overlapping points will be omitted.

The heating-element mounting substrate 51 shown in FIG. 5 is identical with the heating-element mounting substrate 50 shown in FIGS. 1 and 2, except that the semiconductor device 1 is mounted onto an upper surface of a circuit board 10a having different configuration from that of the circuit board 10 of the first embodiment.

In other words, in the heating-element mounting substrate 51 of the second embodiment, the circuit board 10a has two bending portions 81 and 82 in the planar direction of the right side of the circuit board 10a getting away from the first area 15 (heat radiation metal plate 7). Among them, the bending portion 81 is bended to the side of the upper surface of the wiring 4 and the bending portion 82 is bended to the side of the lower surface of the insulating part 6. Consequently, the two bending portions 81 and 82 are bended in the opposite direction to each other. Furthermore, the circuit board 10a has two bending portions 83 and 84 in the planar direction of the left side of the circuit board 10a getting away from the first area 15 (heat radiation metal plate 7). Among them, the bending portion 83 is bended to the side of the upper surface of the wiring 4 and the bending portion 84 is bended to the side of the lower surface of the insulating part 6. Consequently, the two bending portions 83 and 84 are bended in the opposite direction to each other. If the circuit board 10a provides with such bending portions 81 to 84, the heat radiation metal plate 7 positioned in the first area 15 is arranged in a concave portion 96 formed by protruding from the whole of the circuit board 10 in the thickness direction of the base material 8. Furthermore, the semiconductor device 1 provided to correspond to the heat radiation metal plate 7 is mounted in the concave portion 96.

The heating-element mounting substrate 51 of the second embodiment described above can also exhibit the same effects as those of electronic-component mounting substrate 50 of the first embodiment.

### Third Embodiment

Next, description will be made on a third embodiment of a heating-element mounting substrates of the present invention.

FIG. 6 is a vertical cross-sectional view which shows a third embodiment of a heating-element mounting substrate of the present invention.

Hereinafter, a heating-element mounting substrate 52 of the third embodiment will be described by focusing differences between the heating-element mounting substrate 50 of the first embodiment and that of the third embodiment, and description of the overlapping points will be omitted.

The heating-element mounting substrate 52 shown in FIG. 6 is identical with the heating-element mounting substrate 50 shown in FIGS. 1 and 2, except that the semiconductor device 1 is mounted onto an upper surface of a circuit board 10b having different configuration from that of the circuit board 10 of the first embodiment.

In other words, in the heating-element mounting substrate 52 of the third embodiment, the circuit board 10b has two bending portions 81 and 82 in the planar direction of the right side of the circuit board 10b getting away from the first area 15 (heat radiation metal plate 7). Among them, the bending portion 81 is bended to the side of the upper surface of the wiring 4 and the bending portion 82 is bended to the side of the lower surface of the insulating part 6. Consequently, the two bending portions 81 and 82 are bended in the opposite direction to each other. Furthermore, the circuit board 10b has two bending portions 83 and 84 in the planar direction of the left side of the circuit board 10b getting away from the first area 15 (heat radiation metal plate 7). Among them, the bending portion 83 is bended to the side of the upper surface of the wiring 4 and the bending portion 84 is bended to the side of the lower surface of the insulating part 6. Consequently, the two bending portions 83 and 84 are bended in the opposite direction to each other.

Both the upper surfaces and the lower surfaces of the wiring 4 and the resin layer 5 are bended at the bending portions 81 to 84 of the heating-element mounting substrate 52, respectively. On the other hand, the upper surface of the insulating part 6 is bended, but the lower surface is not bended. This means that the lower surface of the circuit board 10b is constituted from a flat surface which is formed from the lower surface of the insulating part 6 and the lower surface of the heat radiation metal plate 7

Therefore, if the circuit board 10b provides with such bending portions 81 to 84, the heat radiation metal plate 7 positioned in the first area 15 is arranged so as to correspond to a concave portion 96 formed in the circuit board 10b. Furthermore, the semiconductor device 1 provided to correspond to the heat radiation metal plate 7 is mounted in the concave portion 96.

The heating-element mounting substrate 52 of the third embodiment described above can also exhibit the same effects as those of heating-element mounting substrate 50 of the first embodiment.

### Fourth Embodiment

Next, description will be made on a fourth embodiment of a heating-element mounting substrates of the present invention.

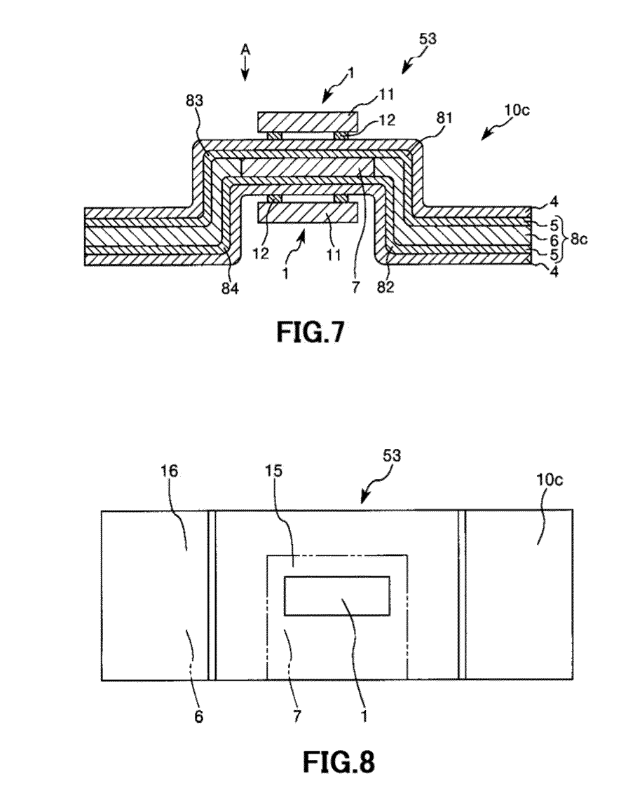

FIG. 7 is a vertical cross-sectional view which shows a fourth embodiment of a heating-element mounting substrate of the present invention. FIG. 8 is a view (plan view) seen from a direction of the arrow A in FIG. 7.

Hereinafter, a heating-element mounting substrate 53 of the fourth embodiment will be described by focusing differences between the heating-element mounting substrate 50 of the first embodiment and that of the fourth embodiment, and description of the overlapping points will be omitted.

The heating-element substrate 53 shown in FIG. 7 is identical with the heating-element mounting substrate 50 shown in FIGS. 1 and 2, except that the semiconductor devices 1 are mounted onto both an upper surface and a lower surface of a circuit board 10c having different configuration from that of the circuit board 10 of the first embodiment, respectively.

In other words, in the heating-element mounting substrate 53 of the fourth embodiment, the circuit board 10c has a base material 8c including a resin layer 5, a heat radiation metal plate 7 covering the resin layer 5 so as to correspond to the first area in the planar view of the resin layer 5, an insulating part 6 covering the resin layer 5 so as to correspond to the second area 15, and a resin layer 5 covering the lower surfaces of the heat radiation metal plate 7 and the insulating part 6; and wirings 4 provided on both an upper surface and a lower surface of the base material 8c. Two semiconductor devices 1 are mounted onto the wirings 4 provided on the base material 8c in a state of being electrically connected with the wirings 4 at the connecting terminals 12 thereof, respectively.

Further, in the base material 8c, the heat radiation metal plate 7 covers the resin layer 5 so as to correspond to the first area 15 in the planar view of the resin layer 5. The insulating part 6 covers the resin layer 5 so as to correspond to the second area 15 in the planar view of the resin layer 5. In this embodiment, the heat radiation metal plate 7 is exposed at a side surface of the base material 8c (circuit board 10c) as shown in FIG. 8. The heat generated in the two semiconductor devices 1 is radiated from an exposure surface of the heat radiation metal plate 7 which is exposed at the side surface.

The heating-element mounting substrate 53 of the fourth embodiment described above can also exhibit the same effects as those of heating-element mounting substrate 50 of the first embodiment.

In this regard, it is to be noted that the heating-element mounting substrate 53 having such a configuration is obtained as follows. First, prepared is a metal foil-clad substrate (metal foil-clad substrate of the present invention) in which metal foils 4A are provided on both the upper surface and the lower surface of the base material 8C, respectively. Next, the patterning of both the metal foils 4A is performed to obtain the wirings 4. Thereafter, the semiconductor devices 1 are mounted onto the wirings 4.

### Fifth Embodiment

Next, description will be made on a fifth embodiment of a heating-element mounting substrates of the present invention.

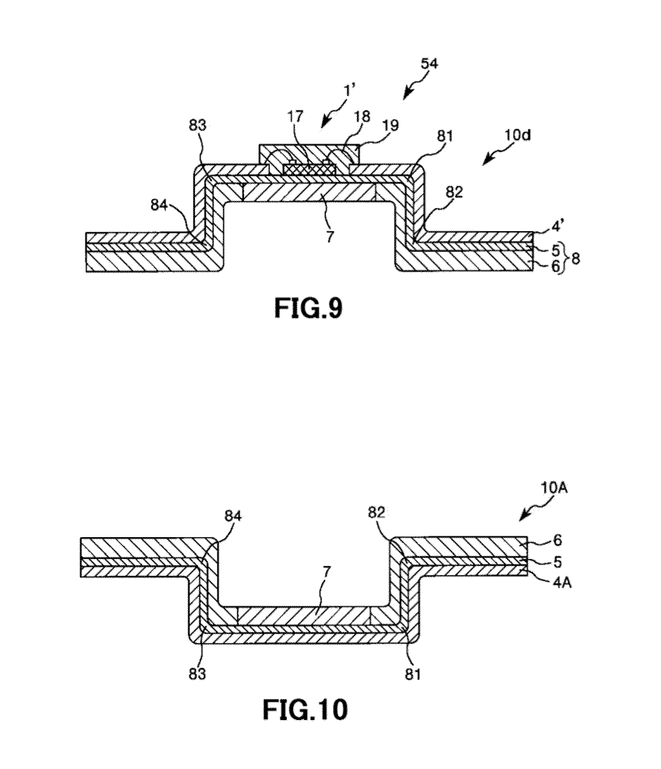

FIG. 9 is a vertical cross-sectional view which shows a fifth embodiment of a heating-element mounting substrate of the present invention.

Hereinafter, a heating-element mounting substrate 54 of the fifth embodiment will be described by focusing differences between the heating-element mounting substrate 50 of the first embodiment and that of the fifth embodiment, and description of the overlapping points will be omitted.

The heating-element mounting substrate 54 shown in FIG. 9 is identical with the heating-element mounting substrate 50 shown in FIGS. 1 and 2, except that the semiconductor device 1′ having a different configuration from that of the semiconductor device 1 of the first embodiment is mounted onto an upper surface of a circuit board 10d which has a different configuration from that of the circuit board 10 of the first embodiment.

In other words, in the heating-element mounting substrate 54 of the fifth embodiment, the circuit board 10d includes a base material 8 and a wiring 4′ having an opening at a position to mount the semiconductor device 1′. The semiconductor device 1′ has a semiconductor element 17; bonding wires 18 electrically connecting the semiconductor device 17 and the wiring 4′ with each other; and a mold part 19 sealing the semiconductor element 17 and the bonding wires 18. The semiconductor element 17 is bonded on the resin layer 5 in the opening of the wiring 4′. Furthermore, terminals of the semiconductor element 17 and terminals of the wiring 4′ are electrically connected with each other through the bonding wires 18. In this state, these are sealed by the mold part 19 at a side of an upper surface of the wiring 4′ so as to cover the opening of the wiring 4′.

In such a heating-element mounting substrate 54, the semiconductor element 17 of the semiconductor device 1′ is bonded to the resin layer 5 of the base material 8. The heat generated in the semiconductor element 17 is radiated through not only the resin layer 5 bonded to the semiconductor element 17 but also the heat radiation metal plate 7. Therefore, it is possible to assist the improvement of the heat radiation efficiency for the heart.

The heating-element mounting substrate 54 of the fifth embodiment described above can also exhibit the same effects as those of heating-element mounting substrate 50 of the first embodiment.

In this regard, in FIG. 9, the resin layer 5 is provided on the heat radiation metal plate 7 in the opening of the wiring 4′. The heat generated in the semiconductor element 17 is transferred to the heat radiation metal plate 7 through the resin layer 5. However, the resin layer 5 is not limited thereto, but may be omitted in the opening of the wiring 4′. In this case, the semiconductor element 17 may be bonded together the heat radiation metal plate 7. By doing so, the heat generated in the semiconductor element 17 may be directly transferred to the heat radiation metal plate 7 without going through the resin layer 5. Such a configuration makes it possible to assist the further improvement of the heat radiation efficiency for the heart generated in the semiconductor element 17.

In this regard, in the first to fifth embodiments, the descriptions have been made on the cases that the circuit boards 10 and 10a to 10d have the four bending portions 81 to 84 formed by bending the insulating part 6, the resin layer 5 and the wiring 4 in the second area 16. However, the circuit board of the present invention is not limited to the cases, but may have one or more of the bending portions. In other words, it may have one bending portion or two or three bending portions, or 5 or more of the bending portions.

Further, the heating-element mounting substrates 50 to 54 may be placed in a housing of an electronic device by attaching to another structure of the electronic device. Further, the heating-element mounting substrates 50 to 54 may be attached to another member (another structure) constituting the housing as a part of the housing of the electronic device so that a surface of the side of the insulating part 6 faces the outside.

As described above, while the description has been made on the embodiments of the metal foil-clad substrate, the circuit board and the heating-element mounting substrate of the present invention shown in the drawings, the present invention is not limited thereto.

Each part constituting the metal foil-clad substrate, the circuit board and the heating-element mounting substrate of the present invention may be substituted with arbitrary parts which can exhibit the same functions. Further, arbitrary parts may be added to the metal foil-clad substrate, the circuit board and the heating-element mounting substrate of the present invention.

Furthermore, the present invention may be a combination of two or more arbitrary parts described in the first to fifth embodiments.

The heating-element mounting substrate of the present invention is not limited to the embodiments described above. In other words, the present invention is not limited to the heating-element mounting substrate in which the semiconductor device as the electronic component is mounted onto the circuit board. The present invention can be applied to the heating-element mounting substrate. In such an heating-element mounting substrate, a resistance (e.g. a thermistor) as the heating element, a powered transistor (e.g. a condenser, a diode powered MOSFET, and an insulated gate bipolar transistor (IGBT)), a light emitting device (e.g. a reactor, a LED (light emitting diode), a LD (laser diode) and an organic EL element), a motor and the like are mounted onto the circuit board.

### EXAMPLE

Hereinafter, description will be made on a concrete example of the present invention. However, the present invention is not limited thereto.

1. Production of Metal Foil-Clad Substrate

A metal foil-clad substrate was produced as follows.

1.1 Preparation of Second Resin Composition (Varnish)

[1] First, weighted were 40.0 parts by mass of a bisphenol F/bisphenol A phenoxy resin (4275 produced by Mitsubishi Chemical Corporation, a weight average molecular weight is 6.0×10⁴, a ratio of a bisphenol F skeleton and a bisophenol A skeleton is 75:25), 55.0 parts by mass of a bisphenol A type epoxy resin (850S produced by DIC Corporation, an epoxy equivalent is 190), 3.0 parts by mass of 2-phenyl imidazole (2PZ produced by SHIKOKU CHEMICALS CORPORATION) and 2.0 parts by mass of γ-glycidoxypropyl trimethoxy silane (KBM-403 produced by Shin-Etsu Chemical Co., Ltd.) as a silane coupling agent. These were dissolved in cyclohexanone of 400 parts by mass and mixed to obtain a mixture. Next, the mixture was stirred by using a high speed stirring device to obtain a varnish containing a resin material.

[2] Next, 800 g of alumina (a commercialized product (Lot No. 2401) produced by Nippon Light Metal Co., Ltd., an average particle size A is 3.2 μm, a primary particle size B is 3.6 μm, and the average particle size A/the primary particle size B=0.9) was weighed. Next, the alumina was added into a plastics container containing pure water of 1300 mL to obtain an alumina solution. Then, the alumina solution was stirred by using a disperser (“R94077” produced by PRIMIX Corporation) providing with a blade having a diameter of 50 mm under conditions of a rotation number of 5000 rpm and a stirring time of 15 minutes. Thus, the alumina was washed.

Thereafter, the alumina solution was left to stand for 15 minutes to obtain a supernatant solution. Next, 50 mL of the supernatant solution was taken with a dropper and it was filtrated to obtain a filtrate. Then, a pH of the filtrate was measured. The supernatant solution was removed by decantation until the pH value was 7.0. Thereafter, the multiple water washing was performed for the alumina described above.

[3] Next, the alumina which had been subjected to the water washing as described above was left for 20 minutes. Then, the supernatant solution was removed by the decantation. Thereafter, 1000 mL of acetone was added into the plastics container to obtain an alumina acetone solution. Then, the alumina acetone solution was stirred by using the disperser under conditions of the rotation number of 800 rpm and the stirring time of 5 minutes.

Thus, the alumina acetone solution was left for 12 hours to obtain a supernatant solution. Then, the supernatant solution was removed.

[4] Next, the alumina after the supernatant solution was removed was transferred to a stainless bat. The alumina was dried by using a total exhaust type and box type drying machine (“PHH-200” produced by Tabai Corp.) under conditions of a drying temperature of 40° C. and a drying time of 1 hour to obtain a washed alumina (filler).

Thereafter, the washed alumina was dried under the conditions of the drying temperature of 200° C. and the drying time of 24 hours, and then was left under the conditions the temperature of 85° C. and 85% RH. Thus, a water content ratio of the washed alumina became 0.18 mass %.

In this regard, the water content ratio of the washed alumina was calculated from a difference between mass of the washed alumina at 25° C. and mass of the washed alumina at 500° C. which were measured by using a differential thermobalance (TG-DTA).

[5] Next, the washed alumina (505.0 parts by mass) was mixed into the varnish containing the resin material, which was prepared in the above step [1] preliminarily, by using the disperser (“R94077” produced by PRIMIX Corporation) under the conditions of the rotation number of 1000 rpm and the stirring time of 120 minutes. Thus, obtained was a second resin composition in which a ratio of the alumina with respect to a solid content of the resin was 83.5 mass % (60.0 volume %).

1.2 Film Formation of Layer for Forming Resin Layer on Meal Foil

The second resin composition obtained in the above 1.1 was coated onto a rough surface of a roll-shaped copper foil (YGP-35 produced by Nippon Denkai, Ltd.) having the width of 260 mm and a thickness of 35 μm with a comma coater. Next, the second resin composition was heated and dried at 100° C. for 3 minutes and 150° C. for 3 minutes to form a layer for forming resin layer (layer) having a thickness of 100 μm on the copper foil. Thus, a laminated body was obtained.

In this regard, when the second resin composition was dried under such conditions, the layer was formed in a semi-curing state. The laminated body was cut in size of the longitudinal of 56 mm and the side of 100 mm to obtain a metal foil.

1.3 Preparation of Tablet-Shaped First Resin Composition

30 parts of a dimethyleneether type resol resin (R-25 produced by Sumitomo Bakelite Co., Ltd.), 7 parts of a methylol type resol resin (PR-51723 produced by Sumitomo Bakelite Co., Ltd.), 4 parts of a novolak type resin (A-1084 produced by Sumitomo Bakelite Co., Ltd.), 15 parts of aluminum hydroxide, 10 parts of a glass fiber (produced by Nitto Boseki Co., Ltd.), 12 parts of a sintered cray, and 22 parts of an organic filler, a curing accelerator, a release agent, a pigment and others were blended to obtain a mixture. Next, the mixture was kneaded with a heat roll to obtain a kneaded material. The kneaded material was cooled. Thereafter, the kneaded material was pulverized to obtain a pulverized material. Then, the pulverized material was formed into a tablet shape to obtain a tablet-shaped first resin composition.

In this regard, as the resol type phenol resin, used was the dimethyleneether type and resol type phenol resin (solid) obtained as follows as a main component thereof. First, phenol (P) and formaldehyde (F) were added at a mol ratio (F/P) of 1.7 into a reaction container having a reflux condenser agitator, a heating device and a vacuum dewatering device. 0.5 parts by weight of zinc acetate with respect to the 100 parts by weight of phenol was added into the reaction container to obtain a mixture. Next, a pH of the mixture was adjusted to 5.5 and a reflux reaction was carried on for 3 hours. Then, steam distillation was carried on at a degree of vacuum of 100 Torr and a temperature of 100° C. for 2 hours to remove unreacted phenol. Further, reaction was carried on at the degree of vacuum of 100 Torr and the temperature of 115° C. for 1 hour to obtain the dimethyleneether type and resol type phenol resin. The dimethyleneether type and resol type phenol resin had a number average molecular weight of 800.

1.4 Formation of Insulating Part onto Resin Layer providing with Heat Radiation Metal Plate

First, the metal foil in which the layer was formed was placed into the cavity 121 of the mold 100 so that the layer faced the upper side. Then, the tablet-shaped first resin composition was placed in the pot 111 while positioning the heat radiation metal plate at substantially a central portion of the layer.

In this regard, it is to be noted that a size of the heat radiation metal plate had the length of 25 mm, the side of 30 mm and the thickness of 1.5 mm.

Next, the plunger 112 is inserted into the pot 111 while heating and melting the first resin composition in the pot 111. Then, the molten first resin composition was filled into the cavity in a state that the first resin composition was heated and pressed. Thus, the molten first resin composition was supplied onto the layer so as to surround the heat radiation metal plate on the layer in the planar view.

The molten first resin composition and the layer were cured, so that the insulating part was formed on the laminated body in which the metal foil and the resin layer were laminated in this order. This insulating part surrounded the heat radiation metal plate in the planar view. Thus, obtained was a metal foil-clad substrate of Example having four bending portions in which the metal foil, the resin layer and the insulating part were bended to the side of the upper surface of the insulating part or the lower surface of the metal foil (see FIG. 10).

The conditions of curing the first resin composition and the layer were set as follows.

Heating temperature: 175° C.

Pressure to press: 5.0 MPa

Heating/Pressing time: 3 minutes

2. Evaluation of Metal Foil-Clad Substrate

The metal foil-clad substrate of the Example was cut along a thickness direction thereof. The obtained cutting plane was observed by using a microscope of 200 magnifications.

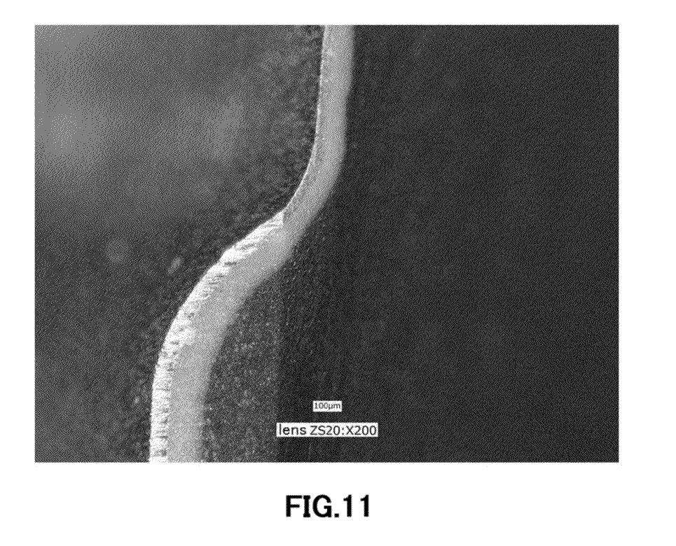

A microscope photograph of the cutting plane which was obtained by the observation with the microscope is shown in FIG. 11.

As clearly seen from the microscope photograph shown in FIG. 11, in the bending portions of the metal foil-clad substrate of the Example, it was found that the metal foil-clad substrate was constituted from the laminated body having the three layers of the metal foil, the resin layer and the insulating part without breakage of the resin layer.

What is claimed is:

1. A metal foil-clad substrate used for forming a circuit board mounting and electrically connecting a heat element generating a heat, the metal foil-clad substrate comprising:
a metal foil having one surface;
a resin layer formed on the one surface of the metal foil;
a heat radiation metal plate formed on a surface of the resin layer opposite to the metal foil and radiating the heat generated by the heat element, wherein the surface of the resin layer includes a first area covering an area to mount the heat element and a second area except the first area in a planer view of the resin layer, and the heat radiation metal plate is formed to correspond to the first area;
an insulating part formed on the surface of the resin layer opposite to the metal foil so as to correspond to the second area in the planer view of the resin layer; and
at least one bending portion in which the metal foil, the resin layer and the insulating part are bended to a side of the metal foil or the insulating part in the second area,
wherein the insulating part is constituted of a cured material of a first resin composition containing a first thermosetting resin, and
wherein the resin layer is constituted of a cured material or a solidified material of a second resin composition containing a resin material.

2. The metal foil-clad substrate as claimed in claim 1, wherein the at least one bending portion includes a plurality of bending portions having two bending portions, and the plurality of bending portion is positioned in a direction of getting away from the first area in the second area, and
wherein one of the two bending portions is bended at the side of the metal foil and the other of the two bending portions is bended at the side of the insulating part.

3. The metal foil-clad substrate as claimed in claim 1, wherein the resin material includes a second thermosetting resin.

4. The metal foil-clad substrate as claimed in claim 3, wherein the second thermosetting resin includes an epoxy resin.

5. The metal foil-clad substrate as claimed in claim 1, wherein the resin material includes a resin component of which weight average molecular weight is in the range of 1.0×10⁴ to 1.0×10⁵.

6. The metal foil-clad substrate as claimed in claim 1, wherein the second resin composition contains a filler further.

7. The metal foil-clad substrate as claimed in claim 6, wherein the filler is a granular body constituted of aluminum oxide as a main component thereof.

8. The metal foil-clad substrate as claimed in claim 6, wherein the filler is dispersed at the side of the insulating part in the resin layer.

9. The metal foil-clad substrate as claimed in claim 1, wherein the first thermosetting resin includes a phenol resin.

10. The metal foil-clad substrate as claimed in claim 1, wherein the first resin composition and the second resin composition are different from each other.

11. The circuit board formed using the metal foil-clad substrate claimed in claim 1, the circuit board comprising:
a circuit formed by performing a patterning of the metal foil, and having terminals to electrically connect the heat element.

12. A heat-element mounting substrate, comprising:
the circuit board claimed in claim 11; and
the heat element mounted onto the circuit board and electrically connected to the terminals.
